(19) United States
(12) Patent Application Publication
(10) Pub. No.: US 2025/0172723 A1
(43) Pub. Date: May 29, 2025

(54) OPTICAL FILM AND DISPLAY DEVICE

(71) Applicant: TOPPAN HOLDINGS INC., Tokyo (JP)

(72) Inventors: Takahiro MORINAGA, Tokyo (JP); Shinya Ishikawa, Tokyo (JP); Yoshiko Ishimaru, Tokyo (JP); Erika Shimada, Tokyo (JP)

(73) Assignee: TOPPAN HOLDINGS INC., Tokyo (JP)

(21) Appl. No.: 19/025,526

(22) Filed: Jan. 16, 2025

Related U.S. Application Data
(63) Continuation of application No. PCT/JP2023/019769, filed on May 26, 2023.

(30) Foreign Application Priority Data
Jul. 20, 2022 (JP) 2022-115440
Jul. 20, 2022 (JP) 2022-115441

(51) Int. Cl. G02B 1/11

(52) U.S. Cl. CPC G02B 1/11

(57) ABSTRACT

An optical film includes a sheet-like transparent substrate, and a colored layer and a functional layer formed on the transparent substrate. The colored layer is made of a cured product containing a dye, an energy radiation-curable compound, a photoinitiator, and a radical scavenger. The dye contains at least one of a first coloring material, a second coloring material, and a third coloring material. When the infrared absorption spectrum peak intensity of the colored layer in the range of 780 to 825 cm⁻¹ is A and the infrared absorption spectrum peak intensity of pentaerythritol tetraacrylate in the range of 780 to 825 cm⁻¹ is B, A/B is 0.01 or more and 0.25 or less. At least one of the transparent substrate and the functional layer has an ultraviolet shielding rate of 85% or higher as measured according to JIS L 1925.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2023/019769, filed on May 26, 2023, which is based upon and claims the benefit to Japanese Patent Application No. 2022-115440, filed on Jul. 20, 2022 and to Japanese Patent Application No. 2022-115441, filed on Jul. 20, 2022; the disclosures of all which are incorporated herein by reference in their entirety.

### TECHNICAL FIELD

The present invention relates to an optical film. A display device using this optical film is also mentioned.

### BACKGROUND

Display devices are often used in environments where there is incident external light, whether indoors or outdoors. The external light incident on the display device is reflected at the surface of the display device, causing a reduction in display quality. In particular, self-luminous display devices such as organic light-emitting display devices tend to have reduced display quality due to their electrodes and many other metal wirings strongly reflecting external light.

In order to reduce the reflectance of the display device and suppress external light reflection, a circular polarizing plate may be disposed on the display surface side of the display device.

Meanwhile, display devices are generally required to have high color purity. Color purity indicates the range of colors a display device can display, and is also called color reproduction range. Therefore, high color purity means a wide color reproduction range and good color reproducibility. Known means of improving color reproducibility include a method in which a color filter is applied to a white light source of the display device to separate colors, and a method in which a color filter for correction is applied to a monochromatic light source to narrow down the full width at half maximum. However, color filters with improved color purity generally have low transmittance and tend to reduce luminance efficiency.

In view of the above, methods for improving color purity without using a color filter have been proposed.

PTL 1 discloses a display filter in which a color correction layer is provided on a film having an antireflection layer and an electromagnetic wave shielding layer. Since this display filter has a configuration in which a color correction layer is provided on an antireflection film, a photolithography process is not required in manufacturing, and luminance efficiency is less likely to decrease.

PTL 2 discloses coloring materials suitable for the color correction layer. It proposes an optical filter including a first coloring material having a specific structure and a second coloring material having a maximum absorption in the wavelength range of 420 to 480 nm.

Self-luminous display devices such as organic light-emitting display devices may strongly reflect external light and therefore tend to have degraded display quality, but are expected to become next-generation display devices because of their superior characteristics such as the ability to reduce size, low power consumption, high luminance, and high response speed.

There is a configuration in which a polarizing plate and a retarder are placed on the display surface side to suppress reflection of external light and thereby solve the problem of drop in display quality due to reflection of external light.

However, in the method using a polarizing plate and a retarder, when the light from the display device passes through the polarizing plate and retarder to be emitted to the outside, a considerable portion of the light is lost. This has tended to reduce the lifespan of the device.

PTL 3 proposes an organic light-emitting display device having a display substrate including organic light-emitting elements and a sealing substrate placed apart from the display substrate. A filler is embedded in the space between the display substrate and the sealing substrate to adjust the transmittance by selectively absorbing external light in one or more specific wavelength bands. According to the invention of PTL 3, in addition to the improvement in visibility achieved by suppressing external light reflection, the color purity is improved because the portion of the light emitted from the display device that is in a wavelength band that particularly reduces color purity is selectively absorbed.

Regarding the improvement in color purity, PTL 4 discloses a configuration containing a dye having maximum absorption wavelengths at least in the wavelength regions 480 to 510 nm and 580 to 610 nm.

[Citation List][Patent Literature][PTL 1] JP 2007-226239 A; [PTL 2] JP 6142398 B; [PTL 3] JP 5673713 B; [PTL 4] JP 2019-56865 A; [PTL 5] WO 2021/066082 A.

### SUMMARY OF THE INVENTION

### Technical Problem

When a color correction layer is formed on a film having an antireflection layer or the like, it is normally manufactured by roll-to-roll processing. In such a case, a certain degree of surface hardness is required to prevent scratches during the manufacturing process. For this reason, a cured product containing an energy radiation-curable compound such as a UV-curable material is generally used as a binder material.

Meanwhile, many of the functional dyes contained in the coloring materials used in the color correction layer do not have high light resistance. The inventors conducted investigations and found that, in the case of a color correction layer using a cured product containing an energy radiation-curable compound as a binder material, the light resistance of the functional dyes is particularly likely to decrease. Therefore, a display filter having such a color correction layer may show significant decreases in the functions of the functional dyes with use, and it is possible that the color correction function cannot be fully exerted.

Further, many wavelength selective absorption dyes have low light resistance and low heat resistance, and may not be able to fully exhibit the effect of improving color purity when their function deteriorates over time.

In relation to this problem, PTL 5 discloses a configuration in which a specific compound is added as an anti-fading agent, and a gas barrier layer is provided. However, the gas barrier layer causes increase in film thickness and cost, and the dyes may deteriorate from defective parts of the gas barrier layer. Furthermore, the inventors have found that when only the anti-fading agent is added without providing the gas barrier layer, the light resistance improves but the heat resistance decreases.

In light of the above circumstances, an object of the present invention is to provide an optical film and a display device that can withstand long-term use.

Another object of the present invention is to provide an optical film and a display device that have a good color correction function, can withstand long-term use, and can be manufactured with good productivity by roll-to-roll processing.

Still another object of the present invention is to provide an optical film and a display device that can maintain high display quality even when used for a long period of time without requiring a gas barrier layer.

### Solution to Problem

The present invention has the following modes.

[1] An optical film including: a sheet-like transparent substrate; a colored layer formed on a side of a first surface of the transparent substrate; and
a functional layer formed on a second surface of the transparent substrate opposite to the first surface or on the colored layer, in which the colored layer is made of a cured product containing a dye (A), an energy radiation-curable compound (B), a photoinitiator (C), and a radical scavenger (D), the dye (A) contains at least one of a first coloring material, a second coloring material, and a third coloring material, the first coloring material has a wavelength of maximum absorption within a range of 470 to 530 nm, and a full width at half maximum of an absorption spectrum of 15 to 45 nm, the second coloring material has a wavelength of maximum absorption within a range of 560 to 620 nm, and a full width at half maximum of an absorption spectrum of 15 to 55 nm, the third coloring material exhibits, within a wavelength range of 380 to 780 nm, a lowest transmittance in a range of 650 to 780 nm, at least one of the transparent substrate and the functional layer has an ultraviolet shielding rate of 85% or higher as measured according to JIS L 1925, and at least one of following item (1) or (2) is satisfied.

(1) When an infrared absorption spectrum peak intensity of the colored layer in a range of 780 to 825 cm−1 is A and an infrared absorption spectrum peak intensity of pentaerythritol tetraacrylate in the range of 780 to 825 cm−1 is B, A/B is 0.01 or more and 0.25 or less.

(2) In a light resistance test in which a xenon lamp with an illuminance of 60 W/cm² (300 to 400 nm) is used to irradiate the optical film from a side having the colored layer for 120 hours under conditions of a temperature of 45° C. and a humidity (RH) of 50% inside a tester, a following formula 1B is satisfied.

$$A 2 \times ( B 2 / C ) - D \leq 0.018 \qquad ( 1 B )$$

[In the above formula (1B), A2 is an infrared absorption spectrum peak intensity at 3450 cm⁻¹ when a straight line connecting absorbances at 3800 cm⁻¹ and 2400 cm⁻¹ is used as a baseline in an infrared absorption spectrum obtained by spectroscopy of reflected light generated by irradiating a surface of the colored layer with infrared light after the light resistance test. B2 is a maximum absorption peak intensity in an infrared absorption spectrum in a range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light before the light resistance test. C is a maximum absorption peak intensity in an infrared absorption spectrum in the range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light after the light resistance test. D is an infrared absorption spectrum peak intensity at 3450 cm⁻¹ when a straight line connecting absorbances at 3800 cm⁻¹ and 2400 cm⁻¹ is used as a baseline in an infrared absorption spectrum obtained by spectroscopy of reflected light generated by irradiating the surface of the colored layer with infrared light before the light resistance test.]

[2] The optical film according to [1], in which the energy radiation-curable compound (B) contains 20 wt % or more of a compound having only two (meth)acryloyl groups.

[3] The optical film according to [1] or [2], in which the radical scavenger (D) is a polymer with a structural unit represented by a following formula (i).

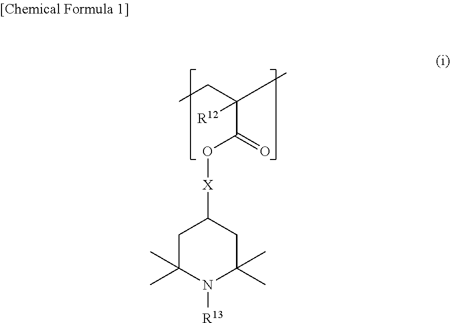

[In the above formula (i), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group; R¹³ represents a hydrogen atom or an alkyl group having 30 or less carbon atoms; and X represents a single bond, an ester group, an aliphatic alkyl chain having 30 or less carbon atoms, an aromatic chain, a polyethylene glycol chain, or a linking group formed by combination thereof, and any of these can contain a spirodioxane ring.]

[4] The optical film according to any one of [1] to [3], in which the functional layer functions as at least one of an antireflection layer and an antiglare layer.

[5] The optical film according to any one of [1] to [4], including an antistatic layer or an antifouling layer as the functional layer.

[6] The optical film according to any one of [1] to [5], in which the dye (A) contains one or more selected from the group consisting of compounds having a porphyrin structure, merocyanine structure, phthalocyanine structure, azo structure, cyanine structure, squarylium structure, coumarin structure, polyene structure, quinone structure, tetradiporphyrin structure, pyrromethene structure, and indigo structure; and a metal complex thereof.

[7] The optical film according to any one of [1] to [6], in which the optical film satisfies the item (1), and the colored layer has at least one of a singlet oxygen quencher and a peroxide decomposer.

[8] The optical film according to [7], in which the optical film satisfies the item (1), and the singlet oxygen quencher is any one of dialkyldithiophosphate, dialkyldithiocarbanate, benzenedithiol, and transition metal complexes thereof.

[9] The optical film according to any one of [1] to [6], in which the optical film satisfies the item (2), and the colored layer contains any one of dialkyldithiophosphate, dialkyldithiocarbanate, benzenedithiol, and transition metal complexes thereof, and a compound represented by a following formula (ii).

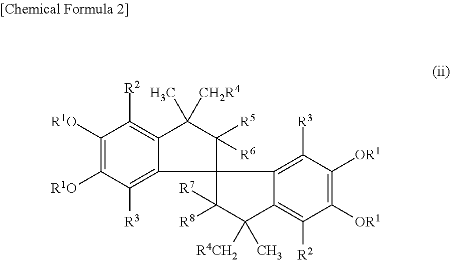

[In the above formula (ii), each R1 independently represents an alkyl group, an alkenyl group, an aryl group, a heterocyclic group, or R⁹CO—, R¹⁰SO₂—, or R¹¹NHCO—. R⁹, R¹⁰, and R¹¹ are each independently an alkyl group, an alkenyl group, an aryl group, or a heterocyclic group. R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.]

[10] The optical film according to any one of [1] to [6] and [9], in which the optical film satisfies the above item (2), and a surface of the colored layer has a pencil hardness of H or higher under a load of 500 g.

[11]A display device including the optical film according to any one of [1] to [10].

The present invention includes the following modes as one aspect.

[A1] An optical film including: a sheet-like transparent substrate; a colored layer formed on a side of a first surface of the transparent substrate; and a functional layer formed on a second surface of the transparent substrate opposite to the first surface or on the colored layer.

The colored layer is a cured product containing a dye (A), an energy radiation-curable compound (B), a photoinitiator (C), and a radical scavenger (D).

The dye (A) contains at least one of a first coloring material, a second coloring material, and a third coloring material. The wavelength of maximum absorption of the first coloring material is within the range of 470 to 530 nm, and the full width at half maximum of the absorption spectrum is 15 to 45 nm. The wavelength of maximum absorption of the second coloring material is within the range of 560 to 620 nm, and the full width at half maximum of the absorption spectrum is 15 to 55 nm. Within the wavelength range of 380 to 780 nm, the third coloring material exhibits the lowest transmittance in the range of 650 to 780 nm.

When the infrared absorption spectrum peak intensity of the colored layer in the range of 780 to 825 cm⁻¹ is A and the infrared absorption spectrum peak intensity of pentaerythritol tetraacrylate in the range of 780 to 825 cm⁻¹ is B, A/B is 0.01 or more and 0.25 or less.

At least one of the transparent substrate and the functional layer has an ultraviolet shielding rate of 85% or higher as measured according to JIS L 1925.

[A2] The optical film according to [A1], in which the energy radiation-curable compound (B) contains 20 wt % or more of a compound having only two (meth)acryloyl groups.

[A3] The optical film according to [A1] or [A2], in which the radical scavenger (D) is a polymer with a structural unit represented by a following formula (i).

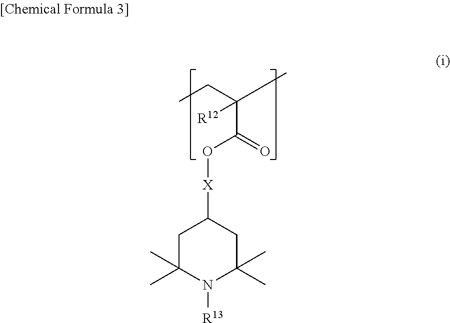

[In the above formula (i), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group; R¹³ represents a hydrogen atom or an alkyl group having 30 or less carbon atoms; and X represents a single bond, an ester group, an aliphatic alkyl chain having 30 or less carbon atoms, an aromatic chain, a polyethylene glycol chain, or a linking group formed by combination thereof, and any of these can contain a spirodioxane ring.]

[A4] The optical film according to any one of [A1] to [A3], in which the functional layer functions as at least one of an antireflection layer and an antiglare layer.

[A5] The optical film according to any one of [A1] to [A4], including an antistatic layer or an antifouling layer as the functional layer.

[A6] The optical film according to any one of [A1] to [A5], in which the colored layer has at least one of a singlet oxygen quencher and a peroxide decomposer.

[A7] The optical film according to [A6], in which the singlet oxygen quencher is any one of dialkyldithiophosphate, dialkyldithiocarbanate, benzenedithiol, and transition metal complexes thereof.

[A8] The optical film according to any one of [A1] to [A7], in which the dye (A) contains one or more selected from the group consisting of compounds having a porphyrin structure, merocyanine structure, phthalocyanine structure, azo structure, cyanine structure, squarylium structure, coumarin structure, polyene structure, quinone structure, tetradiporphyrin structure, pyrromethene structure, and indigo structure; and a metal complex thereof.

[A9]A display device including the optical film according to any one of [A1] to [A8].

The present invention includes the following modes as another aspect.

[B1] An optical film including: a sheet-like transparent substrate; a colored layer formed on a side of a first surface of the transparent substrate; and a functional layer formed on a second surface of the transparent substrate opposite to the first surface or on the colored layer.

The colored layer is a cured product containing a dye (A), an energy radiation-curable compound (B), a photoinitiator (C), and a radical scavenger (D).

The dye (A) contains at least one of a first coloring material, a second coloring material, and a third coloring material. The wavelength of maximum absorption of the first coloring material is within the range of 470 to 530 nm, and the full width at half maximum of the absorption spectrum is 15 to 45 nm. The wavelength of maximum absorption of the second coloring material is within the range of 560 to 620 nm, and the full width at half maximum of the absorption spectrum is 15 to 55 nm. Within the wavelength range of 380 to 780 nm, the third coloring material exhibits the lowest transmittance in the range of 650 to 780 nm.

At least one of the transparent substrate and the functional layer has an ultraviolet shielding rate of 85% or higher as measured according to JIS L 1925.

In a light resistance test in which a xenon lamp with an illuminance of 60 W/cm² (300 to 400 nm) is used to irradiate the optical film from a side having the colored layer for 120 hours under conditions of a temperature of 45° C. and a humidity (RH) of 50% inside a tester, the optical filmi satisfies a following formula 1B.

$$A 2 \times ( B 2 / C ) - D \leq 0.018 \qquad ( 1 B )$$

In the above formula (1B), A2 is the infrared absorption spectrum peak intensity at 3450 cm⁻¹ when the straight line connecting the absorbances at 3800 cm⁻¹ and 2400 cm⁻¹ is used as the baseline in the infrared absorption spectrum obtained by spectroscopy of the reflected light generated by irradiating the surface of the colored layer with infrared light after the light resistance test. B2 is a maximum absorption peak intensity in an infrared absorption spectrum in a range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light before the light resistance test. C is a maximum absorption peak intensity in an infrared absorption spectrum in the range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light after the light resistance test. D is an infrared absorption spectrum peak intensity at 3450 cm⁻¹ when a straight line connecting absorbances at 3800 cm⁻¹ and 2400 cm⁻¹ is used as a baseline in an absorption spectrum obtained by spectroscopy of reflected light generated by irradiating the surface of the colored layer with infrared light before the light resistance test.

[B32] The optical film according to [B1], in which the energy radiation-curable compound (B) contains 20 wt % or more of a compound having only two (meth)acryloyl groups.

[B3] The optical film according to [B1] or [B2], in which the radical scavenger (D) is a polymer with a structural unit represented by a following formula (i).

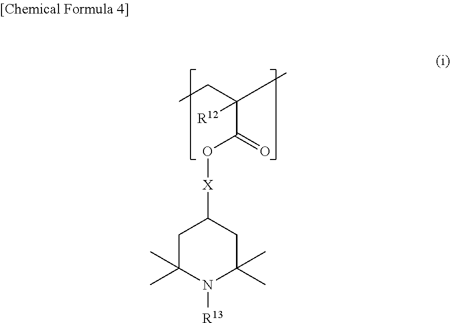

[In the above formula (i), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group; R¹³ represents a hydrogen atom or an alkyl group having 30 or less carbon atoms; and X represents a single bond, an ester group, an aliphatic alkyl chain having 30 or less carbon atoms, an aromatic chain, a polyethylene glycol chain, or a linking group formed by combination thereof, and any of these can contain a spirodioxane ring.]

[B4] The optical film according to any one of [B1] to [B3], in which the colored layer contains any one of dialkyldithiophosphate, dialkyldithiocarbanate, benzenedithiol, and transition metal complexes thereof, and a compound represented by a following formula (ii).

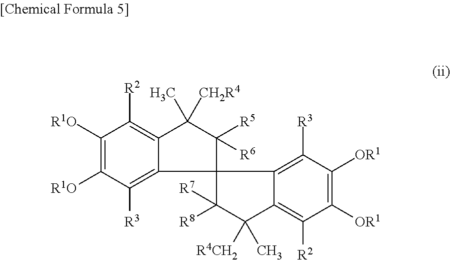

[In the above formula (ii), each R¹ independently represents an alkyl group, an alkenyl group, an aryl group, a heterocyclic group, or R⁹CO—, R¹⁰SO₂—, or R¹¹NHCO—. R⁹, R¹⁰, and R¹¹ are each independently an alkyl group, an alkenyl group, an aryl group, or a heterocyclic group. R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.]

[B5] The optical film according to any one of [B1] to [B4], in which the dye (A) contains one or more selected from the group consisting of compounds having a porphyrin structure, merocyanine structure, phthalocyanine structure, azo structure, cyanine structure, squarylium structure, coumarin structure, polyene structure, quinone structure, tetradiporphyrin structure, pyrromethene structure, and indigo structure; and a metal complex thereof.

[B6] The optical film according to any one of [B1] to [B5], in which a surface of the colored layer has a pencil hardness of H or higher under a load of 500 g.

[B7] The optical film according to any one of [B1] to [B6], in which the functional layer functions as at least one of an antireflection layer and an antiglare layer.

[B8] The optical film according to any one of [B1] to [B7], including an antistatic layer or an antifouling layer as the functional layer.

[B9]A display device including the optical film according to any one of [B1] to [B8].

### Advantageous Effects of the Invention

According to the present invention, an optical film that can withstand long-term use can be provided.

### BRIEF DESCRIPTION OF THE DRAWINGS

FIG. 1 is a cross-sectional view of an optical film according to an embodiment of the present invention.

FIG. 2 is a cross-sectional view of an optical film according to another mode of the present invention.

FIG. 3 is a cross-sectional view of an optical film according to another mode of the present invention.

FIG. 4 is a cross-sectional view of an optical film according to another mode of the present invention.

FIG. 5 is a cross-sectional view of an optical film according to another mode of the present invention.

FIG. 6 is a cross-sectional view of an optical film according to another mode of the present invention.

FIG. 7 is a graph showing the spectrum of a white display output through an organic EL light source and a color filter in Examples.

FIG. 8 is a graph showing the spectra during red, green, and blue output display through the organic EL light source and color filter in the Examples.

### DETAILED DESCRIPTION

With reference to the drawings, some embodiments of the present invention will be described. Throughout the drawings, the same reference signs are given to the same or corresponding components between different embodiments to omit duplicate description.

### First Embodiment

### [Optical Film]

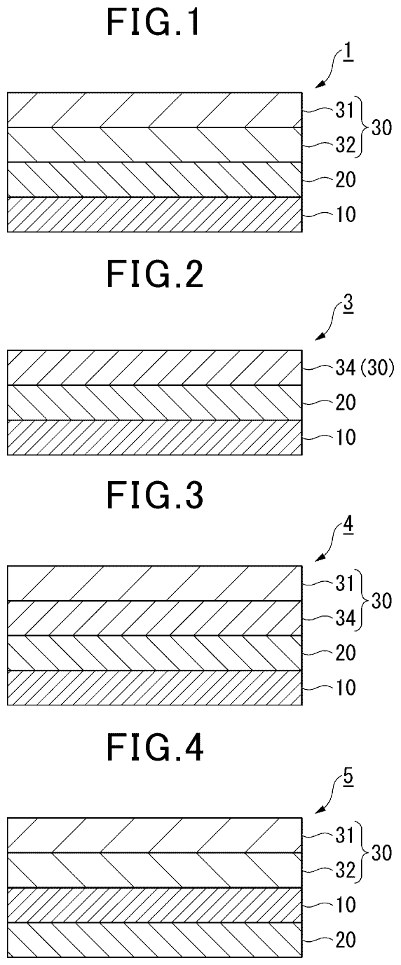

Referring to FIG. 1, an optical film according to a first embodiment of the present invention will be described in detail.

As shown in FIG. 1, the optical film 1 includes a colored layer 10, a transparent substrate 20, and a functional layer 30. The functional layer 30 includes a low refractive index layer 31 and a hard coat layer 32. That is, the optical film 1 has the transparent substrate 20 located on one surface of the colored layer 10 and is a laminate in which the colored layer 10, the transparent substrate 20, the hard coat layer 32, and the low refractive index layer 31 are laminated in this order.

The thickness of the optical film 1 is, for example, preferably in a range of 10 to 140 μm, more preferably 15 to 120 μm, and still more preferably 20 to 100 μm. When the thickness of the optical film 1 is equal to or greater than this lower limit, the strength of the optical film 1 can be further increased. When the thickness of the optical film 1 is equal to or less than the above upper limit, not only the optical film 1 can be more lightweight but also the display device can be thinner.

The following description addresses the individual layers forming the optical film 1.

### <<Colored Layer>>

The colored layer 10 is a cured product of a composition for forming the colored layer containing a dye (A), an energy radiation-curable compound (B), a photoinitiator (C), and a radical scavenger (D).

The thickness of the colored layer 10 is preferably 0.5 to 10 μm, for example. When the thickness of the colored layer 10 is equal to or greater than the lower limit, the colored layer 10 can contain a dye without causing any abnormality in appearance, and the light absorption by the dye improves reflection characteristics and color reproducibility. When the thickness of the colored layer 10 is equal to or less than the above upper limit, it is advantageous in making the display device thinner.

The thickness of the colored layer 10 is determined by observing the cross section of the optical film 1 in the thickness direction using a microscope or the like.

### <Dye (A)>

The dye (A) contains at least one of a first coloring material, a second coloring material, and a third coloring material described below.

The wavelength of maximum absorption of the first coloring material is within the range of 470 to 530 nm, and the full width at half maximum of the absorption spectrum is 15 to 45 nm. When the wavelength of maximum absorption is lower than the lower limit, the luminance efficiency for blue light emission is likely to decrease, and when it exceeds the upper limit, the luminance efficiency for green light emission is likely to decrease. When the full width at half maximum of the absorption spectrum is lower than the lower limit, the effect of suppressing external light reflection is reduced. On the other hand, when it exceeds the upper limit, the external light reflection characteristics tend to improve but the luminance efficiency is likely to decrease.

The wavelength of maximum absorption of the second coloring material is within the range of 560 to 620 nm, and the full width at half maximum of the absorption spectrum is 15 to 55 nm. When the wavelength of maximum absorption is lower than the lower limit, the luminance efficiency for green light emission is likely to decrease, and when it exceeds the upper limit, the luminance efficiency for red light emission is likely to decrease. When the full width at half maximum of the absorption spectrum is lower than the lower limit, the effect of suppressing external light reflection is reduced. On the other hand, when it exceeds the upper limit, the external light reflection characteristics tend to improve but the luminance efficiency is likely to decrease.

Within the wavelength range of 380 to 780 nm, the third coloring material exhibits the lowest transmittance in the range of 650 to 780 nm. When the wavelength at which the transmittance of the third coloring material is lowest within the wavelength range of 380 to 780 nm is lower than the lower limit, the luminance efficiency for red light emission is likely to decrease, and when it exceeds the upper limit, the effect of suppressing external light reflection decreases.

The dye (A) preferably contains a compound having a porphyrin structure, merocyanine structure, phthalocyanine structure, azo structure, cyanine structure, squarylium structure, coumarin structure, polyene structure, quinone structure, tetradiporphyrin structure, pyrromethene structure, or indigo structure; or a metal complex thereof. In particular, it is more preferable to use a metal complex having a porphyrin structure, pyrromethene structure, or phthalocyanine structure, or a compound having a squarylium structure because of their high reliability. The dye (A) may contain only one of these compounds or metal complexes thereof, or two or more of them. These compounds or metal complexes thereof may be contained in the first, second, or third coloring material, or in two or more of these coloring materials.

### <Energy Radiation-Curable Compound (B)>

The energy radiation-curable compound (B) is a resin that is cured by irradiating the resin with active energy radiation such as ultraviolet light or electron beams for polymerization. For example, a monofunctional, bifunctional, trifunctional, or higher (meth)acrylate monomer or urethane (meth)acrylate can be used. Here, “(meth)acrylate” means one or both of “acrylate” and “methacrylate”.

Examples of the monofunctional (meth)acrylate compound that the energy radiation-curable compound (B) may contain include 2-hydroxyethyl (meth)acrylate, 2-hydroxypropyl (meth)acrylate, 2-hydroxybutyl (meth)acrylate, n-butyl (meth)acrylate, isobutyl (meth)acrylate, t-butyl (meth)acrylate, glycidyl (meth)acrylate, acryloylmorpholine, N-vinylpyrrolidone, tetrahydrofurfuryl acrylate, cyclohexyl (meth)acrylate, 2-ethylhexyl (meth)acrylate, isobornyl (meth)acrylate, isodecyl (meth)acrylate, lauryl (meth)acrylate, tridecyl (meth)acrylate, cetyl (meth)acrylate, stearyl (meth)acrylate, benzyl (meth)acrylate, 2-ethoxyethyl (meth)acrylate, 3-methoxybutyl (meth)acrylate, ethyl carbitol (meth)acrylate, phosphate (meth)acrylate, ethylene-oxide-modified phosphate (meth)acrylate, phenoxy (meth)acrylate, ethylene-oxide-modified phenoxy (meth)acrylate, propylene-oxide-modified phenoxy (meth)acrylate, nonyl phenol (meth)acrylate, ethylene-oxide-modified nonyl phenol (meth)acrylate, propylene-oxide-modified nonyl phenol (meth)acrylate, methoxy diethylene glycol (meth)acrylate, methoxy polyethylene glycol (meth)acrylate, methoxy propylene glycol (meth)acrylate, 2-(meth)acryloyl oxyethyl-2-hydroxy propyl phthalate, 2-hydroxy-3-phenoxy propyl (meth)acrylate, 2-(meth)acryloyl oxyethyl hydrogen phthalate, 2-(meth)acryloyl oxypropyl hydrogen phthalate, 2-(meth)acryloyl oxypropyl hexahydro hydrogen phthalate, 2-(meth)acrylol oxypropyl tetrahydro hydrogen phthalate, dimethylaminoethyl (meth)acrylate, trifluoroethyl (meth)acrylate, tetrafluoropropyl (meth)acrylate, hexafluoropropyl (meth)acrylate, octafluoropropyl (meth)acrylate, and adamantine derivative mono(meth)acrylate, such as adamantyl acrylate having monovalent mono(meth)acrylate which is derived from 2-adamantane and adamantine diol. Here, “(meth)acryloyl” means both or one of“acryloyl” and “methacryloyl”.

Examples of the bifunctional (meth)acrylate compound that the energy radiation-curable compound (B) may contain include di(meth)acrylates, such as ethylene glycol di(meth)acrylate, diethylene glycol di(meth)acrylate, butanediol di(meth)acrylate, hexanediol di(meth)acrylate, nonanediol di(meth)acrylate, ethoxylated hexanediol di(meth)acrylate, propoxylated hexanediol di(meth)acrylate, diethylene glycol di(meth)acrylate, polyethylene glycol di(meth)acrylate, tripropylene glycol di(meth)acrylate, polypropylene glycol di(meth)acrylate, neopentyl glycol di(meth)acrylate, ethoxylated neopentyl glycol di(meth)acrylate, tripropylene glycol di(meth)acrylate, and hydroxy pivalate neopentyl glycol di(meth)acrylate.

Examples of the trifunctional or higher (meth)acrylate compound that the energy radiation-curable compound (B) may contain include tri(meth)acrylates such as trimethylolpropane tri(meth)acrylate, ethoxylated trimethylolpropane tri(meth)acrylate, propoxylated trimethylolpropane tri(meth)acrylate, tris2-hydroxyethylisocyanurate tri(meth)acrylate or glycerin tri(meth)acrylate, trifunctional (meth)acrylate compounds such as pentaerythritol tri(meth)acrylate, dipentaerythritol tri(meth)acrylate or ditrimethylolpropane tri(meth)acrylate, polyfunctional (meth)acrylate compounds having three or more functional groups such as pentaerythritol tetra(meth)acrylate, ditrimethylolpropane tetra(meth)acrylate, dipentaerythritol tetra(meth)acrylate, dipentaerythritol penta(meth)acrylate, ditrimethylolpropane penta(meth)acrylate, dipentaerythritol hexa(meth)acrylate or ditrimethylolpropane hexa(meth)acrylate, and polyfunctional (meth)acrylate compounds obtained by substituting part of these (meth)acrylates with an alkyl group or F-caprolactone.

Further, urethane (meth)acrylates can also be used as the resin that the energy radiation-curable compound (B) may contain. Examples of urethane (meth)acrylates include those obtained by reacting a (meth)acrylate monomer having a hydroxyl group with a product of the reaction between a polyester polyol with an isocyanate monomer or a prepolymer.

Examples of these urethane (meth)acrylates include a pentaerythritol triacrylate hexamethylene diisocyanate urethane prepolymer, dipentaerythritol pentaacrylate hexamethylene diisocyanate urethane prepolymer, pentaerythritol triacrylate toluene diisocyanate urethane prepolymer, dipentaerythritol pentaacrylate toluene diisocyanate urethane prepolymer, pentaerythritol triacrylate isophorone diisocyanate urethane prepolymer, and dipentaerythritol pentaacrylate isophorone diisocyanate urethane prepolymer.

The above-listed further monofunctional, bifunctional, trifunctional, or higher (meth)acrylate monomers, urethane (meth)acrylates, or the like that the energy radiation-curable compound (B) can contain may be used alone or in combination of two or more. It may also be a partially polymerized oligomer.

The content of the energy radiation-curable compound (B) is preferably 20 to 80% by mass, more preferably 30 to 70% by mass based on the total mass of the composition for forming the colored layer. When the content of the energy radiation-curable compound (B) is equal to or higher than the lower limit, the effect of suppressing fading can be further enhanced. When the content of the energy radiation-curable compound (B) is equal to or lower than the upper limit, the composition for forming the colored layer can be handled even more easily.

### <Photoinitiator (C)>

For example, when ultraviolet light is used as the active energy radiation, the photoinitiator (C) generates radicals when irradiated with ultraviolet light.

Examples of photoinitiators (C) include benzoins (including benzoin and benzoin alkyl ethers such as benzoin methyl ether, benzoin ethyl ether, and benzoin isopropyl ether), phenyl ketones [for example, acetophenones (including acetophenone, 2-hydroxy-2-methyl-1-phenylpropane-1-one, 2,2-dimethoxy-2-phenylacetophenone, 2,2-diethoxy-2-phenylacetophenone, and 1,1-dichloroacetophenone), alkylphenyl ketones such as 2-hydroxy-2-methylpropiophenone; and cycloalkylphenyl ketones such as 1-hydroxycyclohexylphenyl ketone], aminoacetophenones {including 2-methyl-1-[4-(methylthio)phenyl]-2-morpholinoaminopropanone-1,2-benzyl-2-dimethylamino-1-(4-morpholinophenyl)-butanone-1}, anthraquinones (including anthraquinone, 2-methylanthraquinone, 2-ethylanthraquinone, 2-t-butylanthraquinone, and 1-chloroanthraquinone), thioxanthones (including 2,4-dimethylthioxanthone, 2,4-diethylthioxanthone, 2-chlorothioxanthone, and 2,4-diisopropylthioxanthone), ketals (including acetophenone dimethyl ketal and benzyl dimethyl ketal), benzophenones (including benzophenone), xanthones, and phosphine oxides (for example, 2,4,6-trimethylbenzoyldiphenylphosphine oxide). These photoinitiators may be used singly or in combination of two or more.

The content of the photoinitiator (C) is preferably 0.01 to 20 mass %, more preferably 0.01 to 5 mass % based on the solid content of the composition for forming the colored layer. When the content of the photoinitiator (C) is less than the lower limit, the curing effect will be insufficient. When the content of the photoinitiator (C) exceeds the upper limit, part of the photoinitiator (C) remains unreacted and degrades the reliability of properties such as heat resistance.

### <Radical Scavenger (D)>

The radical scavenger (D) may be a resin having an amine structure. The “amine structure” refers to a structure in which the hydrogen atom of ammonia is replaced with a hydrocarbon group or an aromatic group. Examples of the amine structure include primary amine, secondary amine, and tertiary amine. It may also be a quaternary ammonium cation.

The radical scavenger (D) suppresses dye deterioration (fading) by scavenging radicals and suppressing autooxidation when the dye (A) undergoes oxidative deterioration. An example of a resin that has an amine structure and can be used as the radical scavenger (D) is a resin having a hindered amine structure and a molecular weight of 2000 or higher. When the molecular weight of the resin having a hindered amine structure is 2000 or higher, the effect of suppressing fading can be improved. This is considered to be because many molecules remain in the colored layer 10, and thus a sufficient effect of suppressing fading can be obtained.

The upper limit of the molecular weight of the resin having a hindered amine structure is, for example, about 200,000, but the upper limit is not particularly limited.

The term “molecular weight” as used herein means “mass average molecular weight” measured by gel permeation chromatography (GPC) using polystyrene as the standard substance.

The radical scavenger (D) of this embodiment is a polymer containing a radical scavenging amine structure, and has a structural unit represented by the following formula (i).

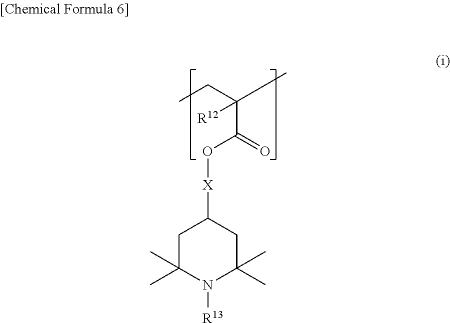

In the above formula (i), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group; R¹³ represents a hydrogen atom or an alkyl group having 30 or less carbon atoms; and X represents a single bond, an ester group, an aliphatic alkyl chain having 30 or less carbon atoms, an aromatic chain, a polyethylene glycol chain, or a linking group formed by combination thereof, and any of these may contain a spirodioxane ring.

R¹² is preferably a hydrogen atom, a hydroxy group, or an alkyl group having 10 or less carbon atoms. The number of carbon atoms in the alkyl group is preferably 1 to 6, more preferably 1 to 3.

R¹³ is preferably a hydrogen atom or an alkyl group having 10 or less carbon atoms. The number of carbon atoms in the alkyl group is preferably 1 to 6, more preferably 1 to 3.

X is preferably a single bond or an aliphatic alkyl chain having 30 or less carbon atoms. The number of carbon atoms in the aliphatic alkyl chain is preferably 10 or less, preferably 1 to 6, more preferably 2 to 4.

In this embodiment, the main component (the component with the highest mass %) of the radical scavenger (D) may be a copolymer of the structural unit represented by the above formula (i) and a copolymer component having one of the following repeating units. It becomes possible to control compatibility with other components by being a copolymer.

Examples of the repeating units include (meth)acrylate repeating units, olefin repeating units, halogen atom-containing repeating units, styrene repeating units, vinyl acetate repeating units, and vinyl alcohol repeating units.

Examples of (meth)acrylate repeating units include repeating units derived from (meth)acrylate monomers having a linear or branched alkyl group in their side chains, and repeating units derived from (meth)acrylate monomers having a hydroxyl group in their side chains.

Examples of the repeating units derived from (meth)acrylate monomers having a linear or branched alkyl group in their side chains include components derived from monomers such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, myristyl (meth)acrylate, pentadecyl (meth)acrylate, hexadecyl (meth)acrylate, heptadecyl (meth)acrylate, and octadecyl (meth)acrylate. These may be used alone or in combination of two or more. Among the above examples, (meth)acrylate repeating units having a linear or branched alkyl group with 1 to 4 carbon atoms in their side chains are preferable.

Examples of the repeating units derived from (meth)acrylic monomers having a hydroxyl group in their side chains include components derived from monomers such as 2-hydroxyethyl (meth)acrylate, 2-hydroxypropyl (meth)acrylate, 4-hydroxybutyl (meth)acrylate, 6-hydroxyhexyl (meth)acrylate, and hydroxyphenyl (meth)acrylate. These may be used alone or in combination of two or more.

Examples of olefinic repeating units include components derived from olefinic monomers such as ethylene, propylene, isoprene, and butadiene. These may be used alone or in combination of two or more.

Examples of halogen atom-containing repeating units include components derived from monomers such as vinyl chloride and vinylidene chloride. These may be used alone or in combination of two or more.

Examples of styrene repeating units include components derived from styrene monomers such as styrene, α-methylstyrene, and vinyltoluene. These may be used alone or in combination of two or more.

Examples of vinyl acetate repeating units include esters of saturated carboxylic acids and vinyl alcohol such as vinyl acetate and vinyl propionate. These may be used alone or in combination of two or more.

An example of a vinyl alcohol repeating unit is vinyl alcohol, and it may have a 1,2-glycol bond in its side chain.

The copolymer may have the structure of a random copolymer, alternating copolymer, block copolymer or graft copolymer. The manufacturing process and preparation with other components are easy when the copolymer has the structure of a random copolymer. Therefore, a random copolymer is preferred to the other copolymers.

Radical polymerization may be used as the polymerization method for obtaining the copolymer. Radical polymerization is preferable because it facilitates industrial production. The radical polymerization may be solution polymerization, emulsion polymerization, bulk polymerization, or suspension polymerization. The radical polymerization is preferably solution polymerization. By using solution polymerization, the molecular weight of the copolymer can be easily controlled.

In the radical polymerization, before adding a polymerization initiator to polymerize the monomers, the monomers may be diluted with a polymerization solvent.

The polymerization solvent may be, for example, an ester solvent, alcohol ether solvent, ketone solvent, aromatic solvent, amide solvent, or alcohol solvent. The ester solvent may be, for example, methyl acetate, ethyl acetate, n-butyl acetate, isobutyl acetate, t-butyl acetate, methyl lactate, or ethyl lactate. The alcohol ether solvent may be, for example, ethylene glycol monomethyl ether, ethylene glycol monoethyl ether, propylene glycol monomethyl ether, propylene glycol monomethyl ether acetate, propylene glycol monoethyl ether, 3-methoxy-1-butanol, or 3-methoxy-3-methyl-1-butanol. The ketone solvent may be, for example, acetone, methyl ethyl ketone, methyl isobutyl ketone, or cyclohexanone. The aromatic solvent may be, for example, benzene, toluene, or xylene. The amide solvent may be, for example, formamide or dimethylformamide. The alcohol solvent may be, for example, methanol, ethanol, n-propanol, isopropanol, n-butanol, isobutanol, s-butanol, t-butanol, diacetone alcohol, or 2-methyl-2-butanol. One of the polymerization solvents described above may be used alone or two or more may be mixed together.

The radical polymerization initiator may be, for example, a peroxide or an azo compound. The peroxide may be, for example, benzoyl peroxide, t-butyl peroxyacetate, t-butyl peroxybenzoate, or di-t-butyl peroxide. The azo compound may be, for example, azobisisobutyronitrile, an azobisamidinopropane salt, an azobiscyanovaleric acid (salt), or 2,2′-azobis[2-methyl-N-(2-hydroxyethyl) propionamide].

When the total amount of monomers is set to 100 parts by mass, the amount of the radical polymerization initiator is preferably 0.0001 parts by mass or higher and 20 parts by mass or lower, more preferably 0.001 parts by mass or higher and 15 parts by mass or lower, and further preferably 0.005 parts by mass or higher and 10 parts by mass or lower. The radical polymerization initiator may be added to the monomers and the polymerization solvent before initiating polymerization, or may be dropped into the polymerization reaction system. Dropping the radical polymerization initiator into the polymerization reaction system for the monomers and the polymerization solvent is preferable in that the heat generation caused by polymerization can be suppressed.

The reaction temperature for radical polymerization is selected as appropriate according to the kinds of radical polymerization initiator and polymerization solvent. The reaction temperature is preferably 60° C. or higher and 110° C. or lower in order to facilitate manufacturing and reaction control.

When the radical scavenger (D) is a polymer with the structural unit represented by formula (i), the content of the structural unit represented by formula (i) is preferably 1 to 95 mol %, more preferably 10 to 90 mol % based on the total molar quantity of the monomers constituting the energy radiation-curable compound (B). When the content of the structural unit represented by formula (i) is within this range, the light resistance and heat resistance of the dye (A) are improved, which in turn assists fading suppression.

The colored layer 10 may contain a solvent (E) or additive (F). The details of these components are explained below.

### <Solvent (E)>

The solvent (E) is required during the formation of the colored layer. Most of it disappears from the colored layer by volatilization or the like during the drying process after coating, but since a portion of it remains in the colored layer, its component(s) will be described.

Examples of the solvent (E) include ethers, ketones, esters, and cellosolves. Examples of ethers include dibutyl ether, dimethoxymethane, dimethoxyethane, diethoxyethane, propylene oxide, 1,4-dioxane, 1,3-dioxolane, 1,3,5-trioxane, tetrahydrofuran, anisole, and phenetole. Examples of ketones include acetone, methyl ethyl ketone, diethyl ketone, dipropyl ketone, diisobutyl ketone, methyl isobutyl ketone, cyclopentanone, cyclohexanone, methylcyclohexanone, and ethylcyclohexanone. Examples of esters include ethyl formate, propyl formate, n-pentyl formate, methyl acetate, ethyl acetate, methyl propionate, ethyl propionate, n-pentyl acetate, and 7-butyrolactone. Examples of cellosolves include methyl cellosolve, cellosolve (ethyl cellosolve), butyl cellosolve, and cellosolve acetate. One or a combination of two or more of the solvents (E) may be used.

The content of the solvent (E) is preferably 20 to 80 mass %, more preferably 30 to 70 mass % relative to the total mass of the composition for forming the colored layer containing (A) to (D) described above. When the content of the solvent (E) is equal to or higher than the lower limit, the composition for forming the colored layer can be handled even easier. When the content of the solvent (E) is equal to or lower than the upper limit, the time required to form the colored layer can be reduced.

### <Additive (F)>

Specific examples of the additive (F) include singlet oxygen quenchers, peroxide decomposers, leveling agents, antifoaming agents, antioxidants, ultraviolet absorbers, photostabilizers, photosensitizers, and conductive materials.

Examples of singlet oxygen quenchers include dialkyldithiophosphate, dialkyldithiocarbanate, benzenedithiol, and transition metal complexes thereof.

The light resistance and heat resistance of the dye (A) can be improved when the colored layer contains a singlet oxygen quencher.

The inventors have conducted various studies on a configuration that ensures a surface hardness sufficient to withstand production by roll-to-roll processing while preventing a decrease in the light resistance of the functional coloring materials. As a result, they have found that this can be achieved by controlling the infrared absorption spectrum peak intensity of the colored layer in the range of 780 to 825 cm⁻¹ so that it falls within a predetermined range, and further incorporating a radical scavenger. Specifically, when the infrared absorption spectrum peak intensity of the colored layer 10 in the range of 780 to 825 cm⁻¹ is A and the infrared absorption spectrum peak intensity of pentaerythritol tetraacrylate in the range of 780 to 825 cm⁻¹ is B, both good surface hardness and good light resistance can be achieved by making A/B 0.01 or more and 0.25 or less. Details will be shown later using examples, but when the A/B ratio was less than 0.01, the hardness of the cured colored layer was insufficient, and when it exceeded 0.25, the light resistance was more likely to be insufficient.

Although the detailed mechanism by which the colored layer 10 according to this embodiment provides these effects has not been completely clarified, it is known that the infrared absorption spectrum peak intensity in the range of 780 to 825 cm⁻¹ serves as an index of the extent of double bonding. It is considered that, since the amount of double bonds is prevented from becoming excessive while securing a certain amount of double bonds in the structure of the colored layer to impart hardness, the colored layer 10 according to this embodiment can suppress a decrease in light resistance by suppressing the generation of radicals or the like that deteriorate the functional coloring materials when light is incident on the double bonds, and also capturing the generated radicals by the radical scavenger.

To adjust the value of A/B, it is effective to use a compound having only two (meth)acryloyl groups as a material used for the energy radiation-curable compound (B). The inventors have found through their investigations that when the energy radiation-curable compound (B) contains 20 wt % or more of a compound having only two (meth)acryloyl groups, the above-mentioned preferred range of A/B can be easily realized.

### <<Transparent Substrate>>

The transparent substrate 20 is a sheet-like member located on one surface of the colored layer 10 and forming an optical film 1.

A resin film having translucency may be used as the transparent substrate 20. The forming material of the transparent substrate 20 may be a transparent resin or inorganic glass. Examples of transparent resin include polyolefin, polyester, polyacrylate, polyamide, polyimide, polyarylate, polycarbonate, triacetyl cellulose, polyvinyl alcohol, polyvinyl chloride, cycloolefin copolymer, norbornene-containing resin, polyether sulfone, and polysulfone. Examples of polyolefins include polyethylene polypropylene. Examples of polyesters include polyethylene terephthalate, polybutylene terephthalate, and polyethylene naphthalate. An example of polyacrylate is polymethyl methacrylate. Examples of polyamides include nylon 6 and nylon 6,6. Among these, suitable examples are a film of polyethylene terephthalate (PET), a film of triacetyl cellulose (TAC), a film of polymethyl methacrylate (PMMA), and a film of polyester other than PET.

Although the thickness of the transparent substrate 20 is not specifically limited, it is preferably in a range of 10 to 100 μm, for example.

The transmittance of the transparent substrate 20 is preferably, for example, 90% or higher.

The transparent substrate 20 may be provided with the ability to absorb ultraviolet light. The transparent substrate 20 can be given the ability to absorb ultraviolet light by adding an ultraviolet absorber to the resin material of the transparent substrate 20.

Examples of ultraviolet absorbers include salicylic acid ester ultraviolet absorbers, benzophenone ultraviolet absorbers, benzotriazole ultraviolet absorbers, benzotriazine ultraviolet absorbers, and cyanoacrylate ultraviolet absorbers.

These ultraviolet absorbers may be used singly or in combination of two or more.

When the transparent substrate 20 is provided with the ability to absorb ultraviolet light, it preferably has an ultraviolet shielding rate of 85% or higher. The ultraviolet shielding rate is a value measured in accordance with JIS L 1925, and is calculated by the following formula.

Ultraviolet shielding rate (%)=100−average transmittance of ultraviolet light with a wavelength of 290 to 400 nm (%)

An ultraviolet shielding rate below 85% reduces the effect of suppressing fading with regard to the light resistance of the dye (A).

### <<Functional Layer>>

The functional layer 30 is located on the one or the other surface of the colored layer 10. By having the functional layer 30, the optical film can exhibit various functions.

Examples of the functions of the functional layer 30 include antireflection function, antiglare function, antistatic function, antifouling function, reinforcement function, and ultraviolet absorption function (ability to absorb ultraviolet).

The functional layer 30 may have a monolayer or multilayer structure. The functional layer 30 may have one function or two or more functions.

When the optical film 1 has an antireflection function, the functional layer 30 functions as an antireflection layer. Examples of the antireflection layer include the hard coat layer 32, an antiglare layer 34, and a low refractive index layer 31 having a lower refractive index than the transparent substrate 20, which will be described later. The low refractive index layer 31 can be formed by using, for the functional layer, a material having a lower refractive index than the materials of the hard coat layer 32, the antiglare layer 34, and the transparent substrate 20.

To adjust the refractive index of the low refractive index layer 31, fine particles of lithium fluoride (LiF), magnesium fluoride (MgF₂), sodium hexafluoroaluminum (cryolite, 3NaF·AlF₃, Na₃AlF₆), or aluminum fluoride (AlF₃), or fine silica particles may be added. It is effective to use particles having internal voids, such as fine, porous silica particles or hollow silica particles, as the fine silica particles to reduce the refractive index of the low refractive index layer 31. The photoinitiator (C), solvent (E), or additive (F) described in relation to the colored layer 10 may be added to the composition for forming the low refractive index layer 31 (composition for forming a low refractive index layer) as appropriate.

The refractive index of the low refractive index layer 31 is preferably 1.20 to 1.55.

Although the thickness of the low refractive index layer 31 is not specifically limited, it is preferably in a range of 40 nm to 1 μm, for example.

When the optical film 1 has an antiglare function, the functional layer 30 functions as an antiglare layer 34. The antiglare layer 34 has small irregularities on its surface so that they scatter external light to suppress reflection and in turn improve display quality. When combined with the low refractive index layer 31, the low refractive index layer 31 and the antiglare layer 34 constitute an antireflection layer.

The antiglare layer 34 contains at least one selected from fine organic particles and fine inorganic particles as necessary. The fine organic particles are materials that form small irregularities on the surface and provide the function of scattering external light. Examples of fine organic particles include resin particles of translucent resin materials such as acrylic resin, polystyrene resin, styrene-(meth)acrylate copolymers, polyethylene resin, epoxy resin, silicone resin, polyvinylidene fluoride, and polyethylene fluoride resin. In order to adjust the refractive index and the dispersibility of resin particles, two or more kinds of resin particles having different characteristics (refractive indexes) may be mixed.

The fine inorganic particles are a material for controlling sedimentation and aggregation of the fine organic particles. Examples of fine inorganic particles include fine silica particles, fine metal oxide particles, and fine particles of various minerals. Examples of fine silica particles include colloidal silica, and fine silica particles surface-modified with a reactive functional group such as a (meth)acryloyl group. Examples of fine metal oxide particles include fine particles of alumina (aluminum oxide), zinc oxide, tin oxide, antimony oxide, indium oxide, titania (titanium dioxide), and zirconia (zirconium dioxide). Examples of fine mineral particles include fine particles of mica, synthetic mica, vermiculite, montmorillonite, iron-montmorillonite, bentonite, beidellite, saponite, hectorite, stevensite, nontronite, magadiite, ilerite, kanemite, layered titanate, smectite, and synthetic smectite. The fine mineral particles may either be natural or synthetic (including substituted products and derivatives), and also a mixture of both may be used. Among these fine mineral particles, organic layered clay is more preferable. Organic layered clay refers to a swellable clay in which organic onium ions are introduced between layers. The organic onium ion is not particularly limited as long as it can make the swellable clay organic by using the cation exchange properties of the swellable clay. When an organic layered clay mineral is used as the fine mineral particles, the above-described synthetic smectite can be suitably used. Synthetic smectite has the function of increasing the viscosity of the coating liquid for forming the antiglare layer. This suppresses the sedimentation of resin particles and fine inorganic particles and adjusts the shape of the irregularities on the surface of the antiglare layer 34 (functional layer 30).

When the optical film 1 has an antistatic function, the functional layer 30 functions as an antistatic layer. Examples of the antistatic layer include layers containing antistatic agents such as fine metal oxide particles such as antimony-doped tin oxide (ATO) and tin-doped indium oxide (ITO), polymeric conductive compositions, and quaternary ammonium salts.

The antistatic layer may be provided on the outermost surface of the functional layer 30 or between the functional layer 30 and the transparent substrate 20. Alternatively, the antistatic layer may be formed by adding an antistatic agent to one of the above-described layers constituting the functional layer 30. When an antistatic layer is provided, the optical film preferably has a surface resistance of 1.0×10⁶ to 1.0×10¹² (Ω/cm).

When the optical film 1 has an antifouling function, the functional layer 30 functions as an antifouling layer. The antifouling layer improves the antifouling performance by imparting both or one of water repellency and oil repellency. Examples of the antifouling layer include layers containing antifouling agents such as silicon oxide, fluorine-containing silane compounds, fluoroalkylsilazane, fluoroalkylsilane, fluorine-containing silicon compounds, and perfluoropolyether group-containing silane coupling agents.

The antifouling layer may be provided on the outermost surface of the functional layer 30, or formed by adding an antifouling agent to the outermost layer of the functional layer(s) 30.

When the optical film 1 has a reinforcement function, the functional layer 30 functions as a reinforcement layer. The reinforcement layer is a layer that reinforces the optical film. An example of the reinforcement layer is the hard coat layer 32. Examples of the hard coat layer 32 include layers formed with a hard coat agent containing monofunctional, bifunctional, trifunctional, or higher-functional (meth)acrylate or urethane (meth)acrylate.

When the optical film 1 has the ability to absorb ultraviolet light, the functional layer 30 functions as an ultraviolet absorbing layer. Examples of the ultraviolet absorbing layer include layers containing triazine ultraviolet absorbers such as 2-(4,6-diphenyl-1,3,5-triazin-2-yl)-5-hexyloxyphenol and benzotriazole ultraviolet absorbers such as 2-(2H-benzotriazole-2-yl)-4-methylphenol.

The content of the ultraviolet absorber is preferably 0.1 to 5 mass % based on the total mass of the materials forming the ultraviolet absorbing layer. When the content of the ultraviolet absorber is equal to or higher than the lower limit, the functional layer 30 can be provided with sufficient ultraviolet absorbance. When the content of the ultraviolet absorber is equal to or lower than the upper limit, it is possible to avoid insufficient hardness due to a decrease in the amount of the curing component.

In the optical film 1, one or both of the transparent substrate 20 and the functional layer 30 have an ultraviolet shielding rate of 85% or higher, preferably 90% or higher, more preferably 95% or higher. It may even be 100%. When the ultraviolet shielding rate is equal to or higher than the lower limit, light resistance and heat resistance can be further improved.

The ultraviolet shielding rate can be measured according to the method described in JIS L 1925.

The ultraviolet shielding rate can be adjusted by imparting ultraviolet absorbing ability to one or both of the transparent substrate 20 and the functional layer 30.

The thickness of the functional layer 30 is, for example, preferably in a range of 0.04 to 25 m, more preferably 0.1 to 20 m, and still more preferably 0.2 to 15 m. When the thickness of the functional layer 30 is equal to or greater than the lower limit, it becomes easier to impart various functions to the optical film 1. When the thickness of the functional layer 30 is equal to or smaller than the upper limit, it is advantageous in making the display device thinner.

### [Method of Manufacturing Optical Film]

The optical film 1 of this embodiment can be manufactured by a conventionally known method.

For example, the colored layer 10 may be obtained by applying a composition for forming the colored layer containing (A) to (D) described above (and possibly (E) and/or (F)) to one surface of the transparent substrate 20 and curing the composition by irradiating it with active energy radiation.

The light source for irradiating the composition for forming the colored layer with active energy radiation to cure it and form the colored layer 10 can be any light source that generates active energy radiation. Examples of the active energy radiation include optical energy radiation such as radiation (such as gamma rays and X-rays), ultraviolet light, visible light, and electron beams (EB). Usually ultraviolet light and electron beams are used. Examples of lamps emitting ultraviolet light include low-pressure mercury vapor lamps, medium-pressure mercury vapor lamps, high-pressure mercury vapor lamps, carbon arc lamps, metal halide lamps, xenon lamps, and electrodeless lamps. As irradiation conditions, the integrated UV irradiation amount is usually 100-1000 mJ/cm².

Next, a hard coat agent is applied to the other surface of the transparent substrate 20. As with the colored layer 10, the applied hard coat agent is irradiated with active energy radiation to cure it, thereby obtaining the hard coat layer 32.

By forming the low refractive index layer 31 on the hard coat layer 32, an optical film 1 having the functional layer 30 on the other surface of the transparent substrate 20 can be obtained.

The method of forming the low refractive index layer 31 is not particularly limited. For example, it may be formed by applying a composition for forming a low refractive index layer to the hard coat layer 32 and irradiating the applied composition with active energy radiation to cure it, vacuum evaporation, sputtering, ion plating, an ion beam method, or plasma-enhanced chemical vapor deposition.

### OTHER EMBODIMENTS

As shown in FIG. 2, the optical film may be an optical film 3 in which the transparent substrate 20 is located on one surface of the colored layer 10, and the colored layer 10, the transparent substrate 20, and the antiglare layer 34 are laminated in this order. In the optical film 3, the antiglare layer 34 forms the functional layer 30.

Since the optical film 3 of this embodiment has the antiglare layer 34, it has excellent antireflection properties.

As shown in FIG. 3, the optical film may be an optical film 4 in which the transparent substrate 20 is located on one surface of the colored layer 10, and the colored layer 10, the transparent substrate 20, the antiglare layer 34, and the low refractive index layer 31 are laminated in this order. In the optical film 4, the antiglare layer 34 and the low refractive index layer 31 constitute the functional layer 30.

Since the optical film 4 of this embodiment has the low refractive index layer 31 and the antiglare layer 34, it has even more excellent antireflection properties.

As shown in FIG. 4, the optical film may be an optical film 5 in which the transparent substrate 20 is located on one surface of the colored layer 10, and the functional layer 30 is located on the other surface of the colored layer 10. In the optical film 5, the transparent substrate 20, the colored layer 10, the hard coat layer 32, and the low refractive index layer 31 are laminated in this order. In the optical film 5, the hard coat layer 32 and the low refractive index layer 31 constitute the functional layer 30.

The optical film 5 of this embodiment has the colored layer 10 and the functional layer 30 having an ultraviolet absorbing function and an antireflection function on one surface of the transparent substrate 20. The ultraviolet absorbing function may be imparted to any of the layers forming the functional layer.

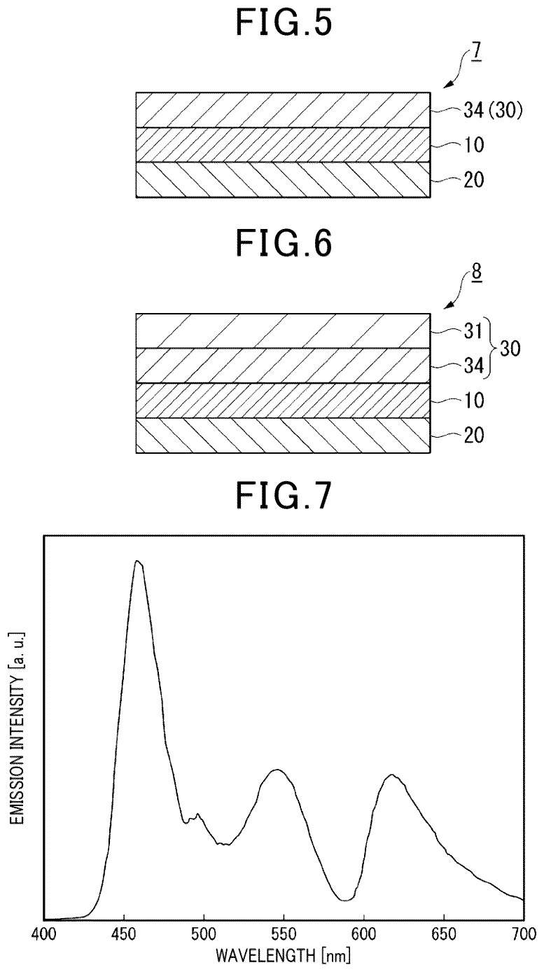

As shown in FIG. 5, the optical film may be an optical film 7 in which the transparent substrate 20 is located on one surface of the colored layer 10, and the antiglare layer 34 is located on the other surface of the colored layer 10. In the optical film 7, the transparent substrate 20, the colored layer 10, and the antiglare layer 34 are laminated in this order. In the optical film 7, the antiglare layer 34 forms the functional layer 30.

Since the optical film 7 of this embodiment has the antiglare layer 34, it has excellent antireflection properties.

In the optical film 7, it is preferable to impart an ultraviolet absorbing function to the antiglare layer 34.

As shown in FIG. 6, the optical film may be an optical film 8 in which the transparent substrate 20 is located on one surface of the colored layer 10, and the functional layer 30 is located on the other surface of the colored layer 10. In the optical film 8, the transparent substrate 20, the colored layer 10, the antiglare layer 34, and the low refractive index layer 31 are laminated in this order. In the optical film 8, the antiglare layer 34 and the low refractive index layer 31 constitute the functional layer 30.

Since the optical film 8 of this embodiment has the low refractive index layer 31 and the antiglare layer 34, it has even more excellent antireflection properties.

In the optical film 8, it is preferable to impart an ultraviolet absorbing function to one of the layers forming the functional layer 30.

### [Display Device]

The display device of the present invention has the optical film of the present embodiment. Specific examples of electronic devices include television, monitors, mobile phones, portable game machines, portable information terminals, personal computers, electronic books, video cameras, digital still cameras, head mounted displays, navigation systems, sound reproduction devices (car audio systems, digital audio players, and the like), copiers, facsimiles, printers, multifunction printers, vending machines, automated teller machines (ATM), personal identification devices, optical communication devices, and IC cards. It can be particularly suitably applied to display devices having self-emissive elements such as LEDs, organic EL, inorganic phosphors, and quantum dots that are susceptible to external light reflection due to metal electrodes and wiring

According to the optical films of the above embodiments, the colored layer 10 has sufficient hardness after curing, and can be produced with good productivity by roll-to-roll processing. Further, the light resistance and heat resistance of the coloring material contained in the colored layer can be improved, and both reflection suppression and luminance efficiency can be achieved. This allows a display device including the optical film of this embodiment to improve display quality and extend the life of the light-emitting elements.

### Second Embodiment

Next, a second embodiment according to the present invention will be described that share a similar basic configuration with the first embodiment. Therefore, similar components will be given the same reference numerals and will not be explained, and only the differences will be explained.

### <<Colored Layer>>

The colored layer 10 is a cured product of a composition for forming the colored layer and contains a dye (A), an active energy radiation-curable resin (B), a photoinitiator (C), and a radical scavenger (D). Since the dye (A), the active energy radiation-curable resin (B), and the photopolymerization initiator (C) are the same as those in the first embodiment, their descriptions will be omitted.

The radical scavenger (D) according to this embodiment is not limited to the polymer described in relation to the radical scavenger (D) according to the first embodiment, and a hindered amine-based photostabilizer or the like can also be used.

As with the first embodiment, the colored layer 10 may contain a solvent (E) or an additive (F). Since the solvent (E) is the same as that in the first embodiment, description thereof will be omitted. Since the additive (F) of the second embodiment is different from that of the first embodiment, it will be described in detail.

### <Additive (F)>

The additive (F) can be, for example, a compound having at least a structure represented by the following formula (ii) (hereinafter referred to as “compound A”), or a sulfur antioxidant.

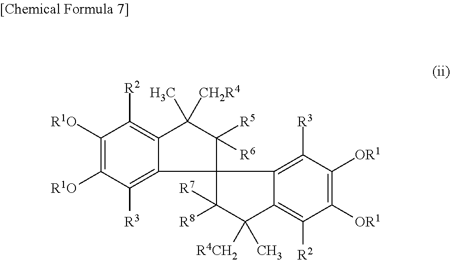

In formula (ii), each R¹ independently represents any one of an alkyl group, an alkenyl group, an aryl group, a heterocyclic group, R⁹CO—, R¹⁰SO₂—, and R¹¹NHCO— (R⁹, R¹⁰, and R¹¹ are each independently any one of an alkyl group, an alkenyl group, an aryl group, and a heterocyclic group). R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.

Examples of the sulfur antioxidant include dialkyldithiophosphate, dialkyldithiocarbanate, benzenedithiol, and transition metal complexes thereof.

Since the colored layer contains the compound A or sulfur antioxidant, the light resistance and heat resistance of the dye (A) can be improved.

The additive (F) may include another additive such as a leveling agent, antifoaming agent, antioxidant, ultraviolet absorber, photostabilizer, photosensitizer, or conductive material.

By containing the composition for forming a colored layer shown by the present embodiment, the colored layer 10 improves light resistance and heat resistance without requiring the gas barrier layer, which makes it possible to achieve both reflection suppression and luminance efficiency, improve display quality, extend the life of the light-emitting elements, and improve color reproducibility.

Note that the additive (F) of the second embodiment may be the same as the additive (F) described for the first embodiment.

Since the optical film of each of the above-described embodiments has a colored layer containing the radical scavenger (D), it is possible to improve light resistance and heat resistance without providing a gas barrier layer, and achieve both reflection suppression and luminance efficiency.

As a result, favorable optical properties can be maintained even when the optical film is subjected to severe load conditions such as those in a light resistance test. More specifically, in a light resistance test in which a xenon lamp with an illuminance of 60 W/cm² (300 to 400 nm) is used to irradiate the sample from the colored layer side for 120 hours under conditions of a temperature of 45° C. and a humidity (RH) of 50% inside the tester, the following formula 1B is satisfied.

$$A 2 \times ( B 2 / C ) - D \leq 0.018 \qquad ( 1 B )$$

In the above formula (1B), A2 is the infrared absorption spectrum peak intensity at 3450 cm⁻¹ when the straight line connecting the absorbances at 3800 cm⁻¹ and 2400 cm⁻¹ is used as the baseline in the infrared absorption spectrum obtained by spectroscopy of the reflected light generated by irradiating the surface of the colored layer with infrared light after the light resistance test.

B2 is a maximum absorption peak intensity in an infrared absorption spectrum in a range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light before the light resistance test.

C is a maximum absorption peak intensity in an infrared absorption spectrum in the range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light after the light resistance test.

D is the infrared absorption spectrum peak intensity at 3450 cm⁻¹ when the straight line connecting the absorbances at 3800 cm⁻¹ and 2400 cm⁻¹ is used as the baseline in the infrared absorption spectrum obtained by spectroscopy of the reflected light generated by irradiating the surface of the colored layer with infrared light before the light resistance test.

The inventors have also found that it is further preferable that the energy radiation-curable compound (B) contains 20 wt % or more of a compound having only two (meth)acryloyl groups, because by preventing the amount of double bonds in the structure of the colored layer from becoming excessive, it is possible to suppress the generation of radicals or the like that deteriorate the functional coloring material when light is incident on the double bonds. Since a certain amount of double bonds is ensured in the structure of the colored layer in such a configuration, the colored layer is provided with sufficient hardness, and the surface of the colored layer can have a pencil hardness of H or higher under a load of 500 g.

A display device including the optical film of this embodiment having the above-described characteristics can improve display quality and extend the life of the light-emitting elements.

Embodiments of the present invention have so far been described in detail with reference to the drawings. However, specific configurations are not limited to this embodiment. The present invention should encompass modifications, combinations, or the like of this embodiment, in the range not departing from the spirit of the present invention.

For example, although the optical films described above have one colored layer, there may be two or more colored layers. In this case, the colored layers may contain the same one or more of the first to third coloring materials or may contain different coloring materials.

In the optical film according to each embodiment, the ultraviolet absorbing ability may be imparted to the transparent substrate 20 or to the functional layer 30 such as the hard coat layer 32. What is important is that the ultraviolet absorbing ability is imparted to a layer that is closer to the screen viewed by the user than the colored layer 10 is when the optical film is attached to the display device.

### EXAMPLES

Now, the present invention will be described more closely using Examples. The technical scope of the present invention should not be limited in any way solely based on the specific contents of these Examples.

### Examples 1 to 13 and Comparative Examples 1 to 9

In the following Examples and Comparative Examples, optical films 1 to 22 having the layer structures shown in Table 1 were prepared. Simulations were performed using the prepared optical films 1 to 22 to evaluate their optical film characteristics, and display device characteristics when applied to an organic EL panel. In the tables, “-” means that the layer is not present.

TABLE 1

| | | | | | | Comp. | Comp. | Comp. | Comp. |
|---|---|---|---|---|---|---|---|---|---|
| | Ex. 1 | Ex. 2 | Ex. 3 | Ex. 4 | Ex. 5 | Ex. 1 | Ex. 2 | Ex. 3 | Ex. 4 |
| Optical | Optical | Optical | Optical | Optical | Optical | Optical | Optical | Optical | Optical |
| film | film 1 | film 2 | film 3 | film 4 | film 5 | film 6 | film 7 | film 8 | film 9 |
| Functional | Low | Low | Low | Low | Low | Low | Low | Low | Low |
| layer 1 | refractive | refractive | refractive | refractive | refractive | refractive | refractive | refractive | refractive |
| | index layer | index layer | index layer | index layer | index layer | index layer | index layer | index layer | index layer |
| Functional | Hard coat | Hard coat | Hard coat | Hard coat | Hard coat | Hard coat | Hard coat | Hard coat | Hard coat |
| layer 2 | layer 1 | layer 1 | layer 1 | layer 1 | layer 1 | layer 1 | layer 1 | layer 1 | layer 1 |
| Colored | — | — | — | — | — | — | — | — | — |
| layer | | | | | | | | | |
| Substrate | TAC | TAC | TAC | TAC | TAC | TAC | TAC | TAC | TAC |
| Colored | Colored | Colored | Colored | Colored | Colored | Colored | Colored | Colored | Colored |
| layer | layer 1 | layer 2 | layer 3 | layer 4 | layer 5 | layer 6 | layer 7 | layer 8 | layer 9 |
| | | | Comp. | Comp. | Comp. | Comp. | | | Comp. |
| | Ex. 6 | Ex. 7 | Ex. 5 | Ex. 6 | Ex. 7 | Ex. 8 | Ex. 8 | Ex. 9 | Ex. 9 |
| Optical | Optical | Optical | Optical | Optical | Optical | Optical | Optical | Optical | Optical |
| film | film 10 | film 11 | film 12 | film 13 | film 14 | film 15 | film 16 | film 17 | film 18 |
| Functional | Low | Low | Low | Low | Low | Low | Low | Low | Low |
| layer 1 | refractive | refractive | refractive | refractive | refractive | refractive | refractive | refractive | refractive |
| | index layer | index layer | index layer | index layer | index layer | index layer | index layer | index layer | index layer |
| Functional | Hard coat | Hard coat | Hard coat | Hard coat | Hard coat | Hard coat | Hard coat | Hard coat | Hard coat |
| layer 2 | layer 1 | layer 1 | layer 1 | layer 1 | layer 1 | layer 1 | layer 1 | layer 1 | layer 1 |
| Colored | — | — | — | — | — | — | — | — | — |
| layer | | | | | | | | | |
| Substrate | TAC | TAC | TAC | TAC | TAC | TAC | TAC | TAC | TAC |
| Colored | Colored | Colored | Colored | Colored | Colored | — | Colored | Colored | Colored |
| layer | layer 10 | layer 11 | layer 12 | layer 13 | layer 14 | | layer 15 | layer 16 | layer 17 |

| | Ex. 10 | Ex. 11 | Ex. 12 | Ex. 13 |
|---|---|---|---|---|
| Optical | Optical | Optical | Optical | Optical |
| film | film 19 | film 20 | film 21 | film 22 |
| Functional | — | Low | Low | — |
| layer 1 | | refractive | refractive | |
| | | index | index | |
| | | layer | layer | |
| Functional | Antiglare | Antiglare | Hard coat | Antiglare |
| layer 2 | layer 1 | layer 1 | layer 2 | layer 2 |
| Colored | — | — | Colored | Colored |
| layer | | | layer | layer |
| | | | 10 | 10 |
| Substrate | TAC | TAC | TAC | TAC |
| Colored | Colored | Colored | — | — |
| layer | layer 10 | layer 10 | | |

### <<Preparation of Optical Film>>

How the layers were formed will be described.

### [Formation of Colored Layer]

The following materials were used to form the colored layer.

Note that the wavelength of maximum absorption, the full width at half maximum, and the wavelength of minimum transmittance in a specified wavelength range of a coloring material are its characteristic values in the state of a cured coating film.

### <Dye (A)>

First coloring material
Dye-1: Pyrromethene cobalt complex dye (with a wavelength of maximum absorption of 493 nm and a full width at half maximum of 26 nm)

### <Production Example of Dye-1>

After placing ethyl 5-formyl-2,4-dimethyl-1H-pyrrole-3-carboxylate (2.5 g) in a reaction vessel to dissolve it in methanol (50 mL), 47% hydrobromic acid (45 g) was added. The mixture was refluxed for 1 hour. By filtering the precipitated solid, 3,3′, 5,5′-tetramethyl-4,4′-di-ethoxycarbonyl-2,2′-dipyrromethene hydrobromide (2.6 g) was obtained.

After placing 3,3′, 5,5′-tetramethyl-4,4′-di-ethoxycarbonyl-2,2′-dipyrromethene hydrobromide (0.6 g) in a reaction vessel, methanol (5 mL), triethylamine (0.17 g), and cobalt acetate tetrahydrate (0.18 g) were added, and the mixture was refluxed for 2 hours. Dye-1 (0.42 g) was obtained by filtering the precipitated solid.
Dye-2: Pyrromethene cobalt complex dye (with a wavelength of maximum absorption of 496 nm and a full width at half maximum of 23 nm)

### <Production Example of Dye-2>

Dye-2 was synthesized in the same manner as in the above <Production example of Dye-1>, except that ethyl 5-formyl-2,4-dimethyl-1H-pyrrole-3-carboxylate was changed to methyl 4-butyl-2-ethyl-5-formyl-1H-pyrrole-3-carboxylate.

### —Second Coloring Material

Dye-3: Tetraazaporphyrin copper complex dye (FDG-007 manufactured by Yamada Chemical Co., Ltd., with a wavelength of maximum absorption of 595 nm and a full width at half maximum of 22 nm)

### —Third Coloring Material

Dye-4: Phthalocyanine copper complex dye (FDN-002 manufactured by Yamada Chemical Co., Ltd., with a wavelength of minimum transmittance of 780 nm within 400 to 780 nm)

### (Other Coloring Materials)

Dye-5: Dye FDG-003 (FDG-003 manufactured by Yamada Chemical Co., Ltd., with a wavelength of maximum absorption of 545 nm and a full width at half maximum of 79 nm)

Note that Dye-5 is used only in the comparative examples for comparison and does not correspond to the second coloring material of the present application.

### <Energy Radiation-Curable Compound (B)>

DCPA: Tricyclodecane dimethanol diacrylate
DCPM: Tricyclodecane dimethanol dimethacrylate
DOGA: Dioxane glycol diacrylate
NP-A: Neopentyl glycol diacrylate
BP-4EAL: EO adduct diacrylate of bisphenol A
PE3A: Pentaerythritol triacrylate
PE4A: Pentaerythritol tetraacrylate
DPHA: Dipentaerythritol hexaacrylate
510H: Dipentaerythritol hexaacrylate hexamethylene diisocyanate urethane prepolymer (UA-510H manufactured by Kyoeisha Chemical Co., Ltd.)
PMMA: Methyl methacrylate polymer (manufactured by FUJIFILM Wako Pure Chemical Corporation)

Although PMMA is not an active energy radiation-curable resin, it is included in this list because it is used only in the comparative examples for comparison.

Also note that “functional” in Table 2 indicates the number of functional groups of (meth)acryloyl groups.

### <Photoinitiator (C)>

Omnirad TPO: An acyl phosphine oxide photoinitiator (manufactured by IGM Resins B.V.)

### <Radical Scavenger (D)>

LA-63P: Hindered amine photostabilizer, ADEKA STAB LA-63P (manufactured by ADEKA CORPORATION)
Resin 1: A polymer containing a structural unit represented by the above formula (i)

### <Production Example of Resin 1>

2.4 g of 1,2,2,6,6-pentamethyl-4-piperidyl methacrylate (FA-711MM manufactured by Showa Denko Materials Co., Ltd.), 5.6 g of methyl methacrylate (manufactured by Kanto Chemical Co., Inc.), 31 g of cyclohexanone (manufactured by Kanto Chemical Co., Inc.), and 0.11 g of 2,2′-azobis(isobutyronitrile) (manufactured by FUJIFILM Wako Pure Chemical Corporation) were placed in a reaction vessel and heated and stirred for 8 hours at 70° C. in a nitrogen gas atmosphere. After that, the mixture was heated and stirred for 1 hour at 100° C. to obtain a polymer solution. This polymer solution was poured into 400 mL of methanol (manufactured by Kanto Chemical Co., Inc.) and then filtered to collect the precipitate. By drying the precipitate, the resin 1 that is a copolymer of 1,2,2,6,6-pentamethyl-4-piperidyl methacrylate:methyl methacrylate=15:85 [mol %] was obtained.

By additionally heating and stirring for an hour at 100° C., the initiator 2,2′-azobis(isobutyronitrile) can be completely decomposed. This suppresses deterioration of the optical film due to the remaining initiator.

By pouring the polymer solution into methanol, unreacted monomers, polymerization solvent, the products of the decomposition of the initiator, and the like can be removed, which suppresses deterioration of the optical film.

### <Solvent (E)>

MEK: Methyl ethyl ketone.
Methyl acetate

### <Additive (F)>

Compound A: T1477 having the structure represented by the below formula (ii). In the structural formula, R¹ is C₃H₇, and R² to R⁸ are H.
Singlet oxygen quencher: Bis(dibutyldithiocarbamic acid) nickel (II) (D1781 manufactured by Tokyo Chemical Industry Co., Ltd.)

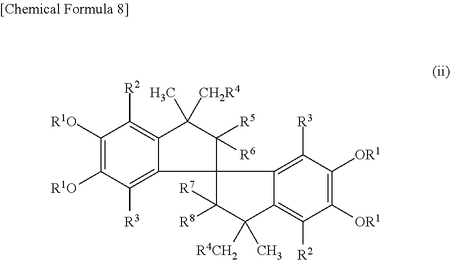

### (Transparent Substrate)

The following films were used for the transparent substrates.
TAC: A triacetyl cellulose film (TG60UL manufactured by FUJIFILM Corporation, substrate thickness 60 μm, ultraviolet shielding rate 92.9%).

### (Formation of Colored Layer)

The compositions for forming colored layers shown in Table 2 were applied onto the transparent substrates shown in Table 1, and dried in an oven at 80° C. for 60 seconds. After that, the coating film was cured by irradiating it with ultraviolet light at an irradiation dose of 150 mJ/cm2 using an ultraviolet irradiation device (a light source, H-bulb, manufactured by Fusion UV Systems Japan) so that a colored layer having a film thickness of 5.0 μm after curing was formed. Note that the amount added is expressed in mass ratio (mass %). In the tables, “-” signifies that the component is not present.

TABLE 2

| Coating liquid for | | | Colored | Colored | Colored | Colored | Colored | Colored | Colored | Colored | Colored |
|---|---|---|---|---|---|---|---|---|---|---|---|
| colored layer | | | layer 1 | layer 2 | layer 3 | layer 4 | layer 5 | layer 6 | layer 7 | layer 8 | layer 9 |
| (A) | Dye | Type | Dye-1 | | | | | | | | |
| | | Amount | 0.20% | | | | | | | | |
| (B) | Energy | Type | DCPA | DCPM | DOGA | NP-A | BP-4EAL | PE3A | PE4A | DPHA | 510H |
| | radiation- | | Bifunctional | | | | | Tri- | Tetra- | Hexa- | Deca- |
| | curable | | | | | | | functional | functional | functional | functional |
| | compound | Amount | 45.9% | | | | | | | | |
| (C) | Initiator | Type | Omnirad TPO | | | | | | | | |
| | | Amount | 1.4% | | | | | | | | |
| (D) | Radical | Type | LA-63P | | | | | | | | |
| | scavenger | Amount | 2.5% | | | | | | | | |
| | Additive | Type | — | — | — | — | — | — | — | — | — |
| | | Amount | — | — | — | — | — | — | — | — | — |

| | | |
|---|---|---|
| Solvent | Type | MEK/methyl acetate = 50/50 |
| | Amount | 50% |

| | | | | | | | |
|---|---|---|---|---|---|---|---|
| Coating liquid for | Colored | Colored | Colored | Colored | Colored | Colored | Colored |
| colored layer | layer 10 | layer 11 | layer 12 | layer 13 | layer 14 | layer 15 | layer 16 |

| | | | | | | | |
|---|---|---|---|---|---|---|---|
| (A) | Dye | Type | Dye-2, Dye-3 | Dye-2 | Dye-1 | Dye-3 | Dye-2/3/ [symbol] |
| | | Amount | 0.2%, 0.5% | 0.17% | 0.06% | 0.8% | 0.20%/0.1 [symbol] |

1.3%

| (B) | Energy | Type | 510H/DCPA = 4/6 | 510H/DCPA = 9/1 | 510H/DPHA = 4/6 | PMMA | 510H/DCPA [symbol] |
|---|---|---|---|---|---|---|---|
| | radiation- | | Deca-functional/ | Deca- | Deca- | Polymer | Deca-functional/bi [symbol] |
| | curable | | bifunctional | functional/ | functional/ | | |
| | compound | | | bifunctional | hexa- | | |
| | | | | | functional | | |

| | | | | | | | |
|---|---|---|---|---|---|---|---|
| Amount | 43.9% | 41.7% | 44.4% | 43.9% | 14.9% | 43.8% | 42.9% |

| (C) | Initiator | Type | Omnirad TPO | | | — | Omnirad T [symbol] |
|---|---|---|---|---|---|---|---|
| | | Amount | 1.4% | | | — | 1.4% |
| (D) | Radical | Type | LA-63P | Resin 1 | LA-63P | — | LA-63P [symbol] |
| | scavenger | Amount | 2.5% | 4.7% | 2.5% | — | 2.5% |

| | | | | |
|---|---|---|---|---|
| Additive | Type | T1477/D1781 = 5/5 | — | T1477/D1781 [symbol] |
| | Amount | 1.5% | — | 1.5% |

| | | |
|---|---|---|
| Solvent | Type | MEK/methyl acetate = 50/50 |

| | | | |
|---|---|---|---|
| Amount | 50% | 85% | 50% |

[symbol]

indicates data missing or illegible when filed

### [Formation of Functional Layer: Hard Coat Layer]

### (Materials of Composition for Forming Hard Coat Layer)

The following materials were used for the composition for forming the hard coat layer.

### —Active Energy Radiation-Curable Resin

UA-306H: Pentaerythritol triacrylate hexamethylene diisocyanate urethane prepolymer (UA-306H manufactured by Kyoeisha Chemical Co., Ltd.)
DPHA
PE3A: Pentaerythritol triacrylate (Light Acrylate PE-3A manufactured by Kyoeisha Chemical Co., Ltd.)

### —Photoinitiator

Omnirad TPO

### —Additive (Ultraviolet (UV) Absorber)

Tinuvin 479: A hydroxyphenyltriazine ultraviolet absorber, Tinuvin (registered trademark) 479 (manufactured by BASF Japan Ltd.)
LA-36: A benzotriazole ultraviolet absorber, ADEKA STAB (registered trademark) LA-36 (manufactured by ADEKA CORPORATION)

### —Solvent

MEK: Methyl ethyl ketone
Methyl acetate

Using these, the two kinds of coating liquids for hard coat layers shown in Table 3 were prepared.

TABLE 3

| | | Hard coat layer 1 | Hard coat layer 2 |
|---|---|---|---|
| Active energy | Type | UA-306H/DPHA/PE3A | |
| radiation-curable | Ratio | 70/20/10 | |
| resin | Amount | 45.4% | 42.2% |
| Photoinitiator | Type | Omnirad TPO | |
| | Amount | 4.6% | |
| UV absorber | Type | — | Tinuvin 479/ |
| | | | LA-36 |
| | Ratio | — | 40/60 |
| | Amount | — | 3.2% |

| | | |
|---|---|---|
| Solvent | Type | MEK/methyl acetate |
| | Ratio | 50/50 |
| | Amount | 50% |

### (Formation of Hard Coat Layer)

The above-described coating liquids for hard coat layers were applied onto the transparent substrates or colored layers shown in Table 1, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan) so that a hard coat layer having a film thickness of 5.0 m after curing was formed. A hard coat layer 1 does not absorb ultraviolet light, whereas a hard coat layer 2 absorbs ultraviolet light.

### [Formation of Functional Layer: Antiglare Layer]

### (Materials of Composition for Forming Antiglare Layer)

The following materials were used for the composition for forming the antiglare layer.

### —Active Energy Radiation-Curable Resin

PE3A

### —Photoinitiator

Omnirad TPO

### Resin Particles

Styrene-methyl methacrylate copolymer particles (refractive index 1.515, average particle size 2.0 μm)

### —Fine Inorganic Particles

Synthetic smectite
Alumina nanoparticles (average particle size 40 nm)

### —Additive (Ultraviolet (UV) Absorber)

Tinuvin 479
LA-36

### —Solvent

Toluene
Isopropyl alcohol

Using these, coating liquids 1 and 2 for antiglare layers having the following compositions were prepared.
Coating liquid 1 for antiglare layer
43.7 parts by mass of PE3A
4.55 parts by mass of Omnirad TPO
0.5 parts by mass of styrene-methyl methacrylate copolymer particles
0.25 parts by mass of synthetic smectite
1.0 parts by mass of alumina nanoparticles
50 parts by mass of toluene/isopropyl alcohol=30/70
Coating liquid 2 for antiglare layer
40.5 parts by mass of PE3A
4.55 parts by mass of Omnirad TPO
0.5 parts by mass of styrene-methyl methacrylate copolymer particles
0.25 parts by mass of synthetic smectite
1.0 parts by mass of alumina nanoparticles
3.2 parts by mass of Tinuvin 479/LA-36=40/60
50 parts by mass of toluene/isopropyl alcohol=30/70

### (Formation of Antiglare Layer)

One of the coating liquids for antiglare layers was applied onto a transparent substrate shown in Table 1, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan) so that an antiglare layer 1 or 2 having a film thickness of 5.0 m after curing was formed. The antiglare layer 1 does not absorb ultraviolet light, whereas the antiglare layer 2 absorbs ultraviolet light.

### (Formation of Functional Layer: Low Refractive Index Layer)

### (Composition for Forming the Low Refractive Index Layer)

The following materials were used for the composition for forming the low refractive index layer.

### —Refractive Index Modifier

8.5 parts by mass of a dispersion of fine, porous silica particles (average particle size 75 nm, solid content 20%) in methyl isobutyl ketone

### —Antifouling Agent

5.6 parts by mass of Optool (registered trademark) AR-110 (manufactured by Daikin Industries, Ltd., solid content 15%, solvent: methyl isobutyl ketone)

### —Active Energy Radiation-Curable Resin

0.4 parts by mass of PE-3A

### —Photoinitiator

0.07 parts by mass of Omnirad TPO

### —Leveling Agent

1.7 parts by mass of RS-77 (manufactured by DIC Corporation)

### —Solvent

83.73 parts by mass of methyl isobutyl ketone

### (Formation of Low Refractive Index Layer)

The above composition for forming the low refractive index layer was applied onto the hard coat layers or antiglare layers shown in Table 1, and dried in an oven at 80° C. for 60 seconds. After that, the coating film was cured by irradiating it with ultraviolet light at an irradiation dose of 200 mJ/cm² using an ultraviolet irradiation device (a light source, H-bulb, manufactured by Fusion UV Systems Japan) so that a low refractive index layer having a film thickness of 100 nm after curing was formed.

The layers of each optical film are laminated in the order shown in Table 1. For example, in the optical film 1 of Example 1, the colored layer 1, the substrate (TAC), the hard coat layer 1, and the low refractive index layer are laminated in this order. That is, the transparent substrate is above the colored layer in Example 1. In the optical film 21 of Example 12, the substrate (TAC), the colored layer 10, the hard coat layer 2, and the low refractive index layer are laminated in this order. That is, the colored layer is above the substrate in Example 12.

### [Evaluation of Film Characteristics]

### <Measurement of Infrared Absorption Spectrum>

For each Example, the infrared absorption spectrum of the colored layer was measured by the ATR method using an FT-IR6300 manufactured by JASCO Corporation. The infrared absorption spectrum of PE4A was also measured in the same manner. The maximum peak height of absorbance in the range of 780 cm⁻¹ to 825 cm⁻¹ was determined in each spectrum. A spectrum was measured 10 times for each sample, and the average value of the maximum peak height values obtained from those measurements was used as the peak intensity height of the sample. The peak intensity of the colored layer was designated as A, the peak intensity of PE4A was designated as B, and A/B was calculated.

### <Ultraviolet Shielding Rate on Colored Layer>

When the transparent substrate was provided above the colored layer, the transmittance was measured using an automatic spectrophotometer (U-4100 manufactured by Hitachi, Ltd.). When the colored layer was provided above the substrate, the layers above the colored layer were peeled off using a transparent pressure-sensitive adhesive tape that satisfies the JIS-K 5600-5-6:1999 adhesion test. Then, using an adhesive tape as a reference, the transmittance of the layers above the colored layer was measured with an automatic spectrophotometer (U-4100). These transmittance values were used to calculate the average transmittance [%] in the ultraviolet region (290 nm to 400 nm), and the ultraviolet shielding rate [%] was obtained by subtracting the average transmittance [%] in the ultraviolet region (290 nm to 400 nm) from 100%.

### <Pencil Hardness Test>

For each Example, in accordance with JIS-K 5400-1990, a pencil hardness test was performed on the surface of the colored layer using a Clemens-type scratch hardness tester (HA-301, manufactured by TESTER SANGYO CO., LTD.) and a pencil (UNI, pencil hardness H, manufactured by Mitsubishi Pencil Co., Ltd.) to which a load of 500 g is applied. The change in appearance due to scratches were evaluated visually, and samples were rated as “Pass” when no scratches were observed, and “Fail” when scratches were observed.

### <Light Resistance Test>

To test the light resistance of the obtained optical films, they were subjected to a xenon weather meter testing machine (X75 manufactured by Suga Test Instruments Co., Ltd.) for 120 hours with a xenon lamp illuminance of 60 W/m2 (300 nm to 400 nm) and at a temperature of 45° C. and humidity (RH) of 50% inside the testing machine. Using the automatic spectrophotometer (U-4100), the transmittance was measured before and after the test. A transmittance difference ΔT before and after the test was calculated at a wavelength, at which the minimum transmittance was obtained within the maximum absorption wavelength ranges of the first to third coloring materials. The evaluation was based on the following three levels, and samples that were not rated as “bad” were considered to have passed.
Good: ΔT is less than 3%
Fair: ΔT is 3% or more and less than 4.5%
Bad: ΔT is 4.5% or more

### [Evaluation of Display Device Characteristics]

### <White Display Transmission Characteristics>

The transmittance of the obtained optical films was measured with an automatic spectrophotometer (U-4100). Using this transmittance, the efficiency of light transmitted through the optical film during the white display was calculated and used as an evaluation of the white display transmission characteristics. As a reference, the efficiency of the spectrum during the white display output through a white organic EL light source and a color filter having the spectrum shown in FIG. 7 was set as 100. The closer it is to 100, the higher the white display transmittance and the better the luminance efficiency.

### <Display Device Reflection Characteristic>

The transmittance T(λ) and surface reflectance R2(λ) were measured for each of the obtained optical films using an automatic spectrophotometer (U-4100). To measure the surface reflectance R2(λ), a matte black dye was applied to the surface of the transparent substrate on which the colored layer and functional layer are not formed to prevent reflection, and the spectral reflectance was measured at an incident angle of 5° and used as the surface reflectance R2(λ). Assuming that the electrode reflectance RE(X) is 100% throughout the wavelength range of 380 nm to 780 nm, without considering any interface reflection or surface reflection at each layer, and setting the reflectance of the display device without the optical film for D65 illuminant (Commission Internationale de l'Eclairage (CIE) standard illuminant D65) as 100, the relative reflection was calculated based on the following formulas (1) to (4). The surface reflectance R(λ) of the outermost layer on the observer's side was used as an evaluation of the display device reflection characteristic. The lower the value of the display device reflection characteristic, the more the reflection of external light can be reduced and the better the reflection characteristic. Note that, in formulas (1) to (4), R1(λ) represents an internal reflection component, Y represents one of the tristimulus values at the white point of the light source D65, PD65(λ) represents the spectrum of D65 illuminant, and overlined y(λ) represents a CIE 1931 color matching function.

$$\begin{matrix}[ Equation 1 ] & \\ R 1 ( λ ) [ \% ] = \frac{( 100 - R 2 ( λ ) )}{100} \times \frac{T ( λ )}{100} \times \frac{T ( λ )}{100} \times {R}_{E} ( λ ) & ( 1 )\end{matrix}$$

$$\begin{matrix}[ Equation 2 ] & \\ R 1 ( λ ) [ \% ] = R 1 ( λ ) + R 2 ( λ ) & ( 2 )\end{matrix}$$

$$\begin{matrix}[ Equation 3 ] & \\ Y = k \times {\int }_{380}^{780} {P}_{D 65} ( λ ) \times R ( λ ) \times \overline{y} ( λ ) d λ & ( 3 )\end{matrix}$$

$$\begin{matrix}[ Equation 4 ] & \\ k = 100 / {\int }_{380}^{780} {P}_{D 65} ( λ ) \times \overline{y} ( λ ) d λ & ( 4 )\end{matrix}$$

### <Color Reproducibility>

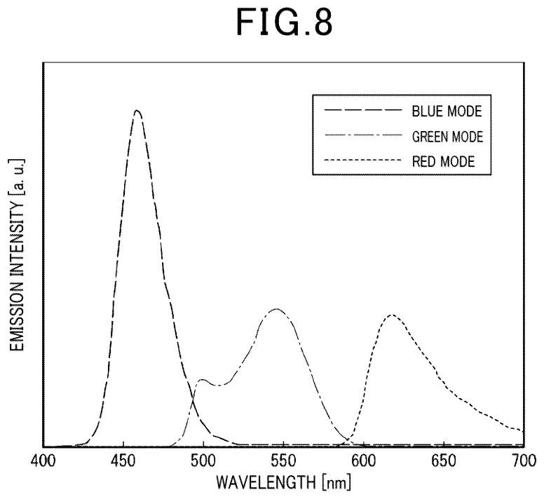

The transmittance of the obtained optical films was measured using an automatic spectrophotometer (U-4100), and the red display, green display, and blue display spectra in FIG. 8 output through the white EL light source and color filter having the spectrum shown in FIG. 7 was measured. The vertical axis of the graphs in FIGS. 7 and 8 indicates emission intensity [arbitrary unit (a. u.)]. The National Television Broadcast Standards Committee (NTSC) ratio was calculated from the CIE 1931 chromaticity value calculated using the measured transmittance and the red display, green display, and blue display spectra in FIG. 8. The NTSC ratio was evaluated as a metric of color reproducibility. The higher the NTSC ratio, the better the color reproducibility.

Table 4 shows the results. The evaluation results of the display device characteristics were carried out for only some of the examples, and the results for the white display transmission characteristics and display device reflection characteristics also include percentages using the values of Comparative Example 8, which does not have a colored layer, as standards (100%).

TABLE 4

| | | | | | | | Comp. | Comp. | Comp. | Comp. |
|---|---|---|---|---|---|---|---|---|---|---|
| | | Ex. 1 | Ex. 2 | Ex. 3 | Ex. 4 | Ex. 5 | Ex. 1 | Ex. 2 | Ex. 3 | Ex. 4 |
| Optical film | | Optical | Optical | Optical | Optical | Optical | Optical | Optical | Optical | Optical |
| | | film 1 | film 2 | film 3 | film 4 | film 5 | film 6 | film 7 | film 8 | film 9 |
| Colored layer | | Colored | Colored | Colored | Colored | Colored | Colored | Colored | Colored | Colored |
| | | layer 1 | layer 2 | layer 3 | layer 4 | layer 5 | layer 6 | layer 7 | layer 8 | layer 9 |
| IR spectrum A/B | | 0.18 | 0.11 | 0.15 | 0.07 | 0.10 | 0.34 | 0.37 | 0.40 | 0.36 |
| UV shielding rate | | 92.0% | 92.0% | 92.0% | 92.0% | 92.0% | 92.0% | 92.0% | 92.0% | 92.0% |
| Evaluation | Light | Excellent | Excellent | Excellent | Good | Good | Bad | Bad | Bad | Bad |
| | resistance | | | | | | | | | |
| | Pencil | Pass | Pass | Pass | Pass | Pass | Pass | Pass | Pass | Pass |
| | hardness | | | | | | | | | |

| | | | | Comp. | Comp. | Comp. | Comp. | | | Comp. |
|---|---|---|---|---|---|---|---|---|---|---|
| | | Ex. 6 | Ex. 7 | Ex. 5 | Ex. 6 | Ex. 7 | Ex. 8 | Ex. 8 | Ex. 9 | Ex. 9 |
| Optical film | | Optical | Optical | Optical | Optical | Optical | Optical | Optical | Optical | Optical |
| | | film 10 | film 11 | film 12 | film 13 | film 14 | film 15 | film 16 | film 17 | film 18 |
| Colored layer | | Colored | Colored | Colored | Colored | Colored | non | Colored | Colored | Colored |
| | | layer 10 | layer 11 | layer 12 | layer 13 | layer 14 | | layer 15 | layer 16 | layer 17 |
| IR spectrum A/B | | 0.25 | 0.24 | 0.30 | 0.38 | 0.00 | — | 0.24 | 0.22 | 0.24 |
| UV shielding rate | | 92.0% | 92.0% | 92.0% | 92.0% | 92.0% | 92.0% | 92.0% | 92.0% | 92.0% |
| Evaluation | Light | Excellent | Excellent | Bad | Bad | Good | No | Excellent | Excellent | Excellent |
| | resistance | | | | | | colored | | | |
| | Pencil | Pass | Pass | Pass | Pass | Fail | layer | Pass | Pass | Pass |
| | hardness | | | | | | | | | |
| White display | | 61.4 | | | | | 91.4 | 61.0 | 59.1 | 61.2 |
| transmittance | | | | | | | | | | |
| characteristics | | | | | | | | | | |
| | Ratio to | 67% | | | | | 100% | 67% | 65% | 67% |
| | Comp. Ex. 8 | | | | | | | | | |
| Display device | | 14.6 | | | | | 33.8 | 16.2 | 13.6 | 20.4 |
| reflectance | | | | | | | | | | |
| characteristics | | | | | | | | | | |
| | Ratio to | 43% | | | | | 100% | 48% | 40% | 60% |
| | Comp. Ex. 8 | | | | | | | | | |
| Color | NTSC | 98.9% | | | | | 91.7% | 100.9% | 97.9% | 85.5% |
| reproducibility | ratio | | | | | | | | | |

| | | | Ex. 10 | Ex. 11 | Ex. 12 | Ex. 13 |
|---|---|---|---|---|---|---|
| Optical film | | | Optical | Optical | Optical | Optical |
| | | | film 19 | film 20 | film 21 | film 22 |
| Colored layer | | | Colored | Colored | Colored | Colored |
| | | | layer 10 | layer 10 | layer 10 | layer 10 |
| IR spectrum A/B | | | 0.24 | 0.24 | 0.22 | 0.23 |
| UV shielding rate | | | 92.0% | 92.0% | 90.5% | 90.5% |
| | Evaluation | Light | Excellent | Excellent | Excellent | Excellent |
| | | resistance | | | | |
| | | Pencil | Pass | Pass | Pass | Pass |
| | | hardness | | | | |
| White display | | | 61.4 | 61.4 | 61.4 | 61.4 |
| transmittance | | | | | | |
| characteristics | | | | | | |
| | | Ratio to | 67% | 67% | 67% | 67% |
| | | Comp. Ex. 8 | | | | |
| Display device | | | 15.6 | 14.6 | 14.6 | 15.6 |
| reflectance | | | | | | |
| characteristics | | | | | | |
| | | Ratio to | 46% | 43% | 43% | 46% |
| | | Comp. Ex. 8 | | | | |
| | Color | NTSC ratio | 98.9% | 98.9% | 98.9% | 98.9% |
| | reproducibility | | | | | |

Among Examples 1 to 13 and Comparative Examples 1 to 9, the optical films according to the Examples all have an A/B ratio of 0.01 or more and 0.25 or less, and exhibit good light resistance and have sufficient hardness.

Comparative Examples 1 to 6, which have an A/B of more than 0.25, were insufficient in light resistance, and Comparative Example 7, which has an A/B of less than 0.01, was insufficient in hardness. Comparative Example 8, which does not have a colored layer, and Comparative Example 9, which does not contain any of the first to third coloring materials, were insufficient in color reproducibility.

Now, the present invention will be described more closely using other Examples. The technical scope of the present invention should not be limited in any way solely based on the specific contents of these Examples.

### Examples 2-1 to 2-10, Comparative Examples 2-1 to 2-8

In the following Examples and Comparative Examples, optical films 2-1 to 2-18 having the layer structures shown in Tables 5 and 6 were prepared. The optical film characteristics of the prepared optical films 2-1 to 2-18, and their display device characteristics when applied to an organic EL panel evaluated by simulations are shown. In the tables, “-” means that the layer is not present.

TABLE 5

| | Ex. 2-1 | Ex. 2-2 | Ex. 2-3 | Ex. 2-4 | Ex. 2-5 |
|---|---|---|---|---|---|
| Optical film structure | Optical | Optical | Optical | Optical | Optical |
| | film 2-1 | film 2-2 | film 2-3 | film 2-4 | film 2-5 |
| Functional layer 1 | Low | Low | Low | Low | Low |
| | refractive | refractive | refractive | refractive | refractive |
| | index layer | index layer | index layer | index layer | index layer |
| Functional layer 2 | Hard coat | Hard coat | Hard coat | Hard coat | Hard coat |
| | layer 1 | layer 1 | layer 1 | layer 1 | layer 1 |
| Functional layer 3 | — | — | — | — | — |
| Colored layer | — | — | — | — | — |
| Transparent | TAC | TAC | TAC | TAC | TAC |
| substrate | | | | | |
| Colored layer | Colored | Colored | Colored | Colored | Colored |
| | layer 2-1 | layer 2-2 | layer 2-3 | layer 2-4 | layer 2-5 |
| | Ex. 2-6 | Ex. 2-7 | Ex. 2-8 | Ex. 2-9 | Ex. 2-10 |
| Optical film structure | Optical | Optical | Optical | Optical | Optical |
| | film 2-6 | film 2-7 | film 2-8 | film 2-9 | film 2-10 |
| Functional layer 1 | Low | Low | Antiglare | Low | Low |
| | refractive | refractive | layer B | refractive | refractive |
| | index layer | index layer | | index layer | index layer |
| Functional layer 2 | Hard coat | Hard coat | | Antiglare | Hard coat |
| | layer 1 | layer 1 | | layer B | layer 2 |
| Functional layer 3 | — | — | — | — | — |
| Colored layer | — | — | — | — | Colored |
| | | | | | layer 2-7 |
| Transparent | TAC | TAC | TAC | TAC | PMMA |
| substrate | | | | | |
| Colored layer | Colored | Colored | Colored | Colored | — |
| | layer 2-6 | layer 2-7 | layer 2-7 | layer 2-7 | |

TABLE 6

| | Comp. | Comp. | Comp. | Comp. | Comp. | Comp. | Comp. | Comp. |
|---|---|---|---|---|---|---|---|---|
| | Ex. 2-1 | Ex. 2-2 | Ex. 2-3 | Ex. 2-4 | Ex. 2-5 | Ex. 2-6 | Ex. 2-7 | Ex. 2-8 |
| Optical film | Optical | Optical | Optical | Optical | Optical | Optical | Optical | Optical |
| structure | film 2-11 | film 2-12 | film 2-13 | film 2-14 | film 2-15 | film 2-16 | film 2-17 | film 2-18 |
| Functional | Low | Low | Low | Low | Low | Low | Low | Low |
| 1 layer 1 | refractive | refractive | refractive | refractive | refractive | refractive | refractive | refractive |
| | index layer | index layer | index layer | index layer | index layer | index layer | index layer | index layer |
| Functional | Hard coat | Hard coat | Hard coat | Hard coat | Hard coat | Hard coat | Hard coat | Hard coat |
| layer 2 | layer 1 | layer 1 | layer 1 | layer 1 | layer 1 | layer 1 | layer 1 | layer 1 |
| Functional | — | — | — | — | — | — | — | — |
| layer 3 | | | | | | | | |
| Colored | — | — | — | — | — | Colored | — | — |
| layer | | | | | | layer 2-13 | | |
| Transparent | TAC | TAC | TAC | TAC | TAC | TAC | TAC | TAC |
| substrate | | | | | | | | |
| Colored | Colored | Colored | Colored | Colored | Colored | — | Colored | — |
| layer | layer 2-8 | layer 2-9 | layer 2-10 | layer 2-11 | layer 2-12 | | layer 2-14 | |

### <<Preparation of Optical Film>>

How the layers were formed will be described.

### [Formation of Colored Layer]

### (Materials of Composition for Forming Colored Layer)

The compositions of the colored layers of the Examples are shown in Table 7, and the compositions of the colored layers of the Comparative Examples are shown in Table 8. The following materials were used.

Note that the wavelength of maximum absorption, the full width at half maximum, and the wavelength of minimum transmittance in a specified wavelength range of a coloring material are its characteristic values in the state of a cured coating film.

### <Dye (A)>

### —First Coloring Material

Dye-1: Pyrromethene cobalt complex dye (with a wavelength of maximum absorption of 493 nm and a full width at half maximum of 26 nm)

### <Production Example of Dye-1>

After placing ethyl 5-formyl-2,4-dimethyl-1H-pyrrole-3-carboxylate (2.5 g) in a reaction vessel to dissolve it in methanol (50 mL), 47% hydrobromic acid (45 g) was added. The mixture was refluxed for 1 hour. By filtering the precipitated solid, 3,3′, 5,5′-tetramethyl-4,4′-di-ethoxycarbonyl-2,2′-dipyrromethene hydrobromide (2.6 g) was obtained.

After placing 3,3′, 5,5′-tetramethyl-4,4′-di-ethoxycarbonyl-2,2′-dipyrromethene hydrobromide (0.6 g) in a reaction vessel, methanol (5 mL), triethylamine (0.17 g), and cobalt acetate tetrahydrate (0.18 g) were added, and the mixture was refluxed for 2 hours. Dye-1 (0.42 g) was obtained by filtering the precipitated solid.

### —Second Coloring Material

Dye-3: Tetraazaporphyrin copper complex dye (FDG-007 manufactured by Yamada Chemical Co., Ltd., with a wavelength of maximum absorption of 595 nm and a full width at half maximum of 22 nm)
Dye-3B: Dye FDG-003 (FDG-003 manufactured by Yamada Chemical Co., Ltd., with a wavelength of maximum absorption of 545 nm and a full width at half maximum of 79 nm)

Note that Dye-3B is used only in the comparative examples for comparison and does not correspond to the second coloring material of the present application.

### —Third Coloring Material

Dye-4: Phthalocyanine copper complex dye (FDN-002 manufactured by Yamada Chemical Co., Ltd., with a wavelength of minimum transmittance of 780 nm within 400 to 780 nm)

### <Active Energy Radiation-Curable Resin (B)>

DCPA: Tricyclodecane dimethanol diacrylate
DCPM: Tricyclodecane dimethanol dimethacrylate
510H: Dipentaerythritol hexaacrylate hexamethylene diisocyanate urethane prepolymer (UA-510H manufactured by Kyoeisha Chemical Co., Ltd.)
PE4A: Pentaerythritol tetraacrylate
DPHA: Dipentaerythritol hexaacrylate
PMMA: Methyl methacrylate polymer (manufactured by FUJIFILM Wako Pure Chemical Corporation)

Although PMMA is not an active energy radiation-curable resin, it is included in this list because it is used only in the comparative examples for comparison.

Also note that “No. of functional groups” in Tables 7 and 8 indicates the number of functional groups of (meth)acryloyl groups.

### <Photoinitiator (C)>

Omnirad TPO: An acyl phosphine oxide photoinitiator (manufactured by IGM Resins B.V.)

### <Radical Scavenger (D)>

LA-63P: Hindered amine photostabilizer, ADEKA STAB LA-63P (manufactured by ADEKA CORPORATION)
Resin 1: A polymer containing a structural unit represented by the above formula (i)

### <Production Example of Resin 1>

2.4 g of 1,2,2,6,6-pentamethyl-4-piperidyl methacrylate (FA-711MM manufactured by Showa Denko Materials Co., Ltd.), 5.6 g of methyl methacrylate (manufactured by Kanto Chemical Co., Inc.), 31 g of cyclohexanone (manufactured by Kanto Chemical Co., Inc.), and 0.11 g of 2,2′-azobis(isobutyronitrile) (manufactured by FUJIFILM Wako Pure Chemical Corporation) were placed in a reaction vessel and heated and stirred for 8 hours at 70° C. in a nitrogen gas atmosphere. After that, the mixture was heated and stirred for 1 hour at 100° C. to obtain a polymer solution. This polymer solution was poured into 400 mL of methanol (manufactured by Kanto Chemical Co., Inc.) and then filtered to collect the precipitate. By drying the precipitate, the resin 1 that is a copolymer of 1,2,2,6,6-pentamethyl-4-piperidyl methacrylate:methyl methacrylate=15:85 [mol %] was obtained.

By additionally heating and stirring for an hour at 100° C., the initiator 2,2′-azobis(isobutyronitrile) can be completely decomposed. This suppresses deterioration of the optical film due to the remaining initiator.

By pouring the polymer solution into methanol, unreacted monomers, polymerization solvent, the products of the decomposition of the initiator, and the like can be removed, which suppresses deterioration of the optical film.

### <Solvent (E)>

MEK: Methyl ethyl ketone.
Methyl acetate

### <Additive (F)>

Compound A: T1477 having the structure represented by the above formula (ii). In the structural formula, R1 is C3H7, and R2 to R8 are H.
D1781: Singlet oxygen quencher (bis(dibutyldithiocarbamic acid) nickel (II), manufactured by Tokyo Chemical Industry Co., Ltd.)

TABLE 7

| Coating liquid for | | Colored | Colored | Colored | Colored | Colored | Colored | Colored |
|---|---|---|---|---|---|---|---|---|
| colored layer | | layer 2-1 | layer 2-2 | layer 2-3 | layer 2-4 | layer 2-5 | layer 2-6 | layer 2-7 |
| Coloring | First | Dye-1 | | — | Dye-1 | Dye-1 | Dye-1 | Dye-1 |
| material | coloring | | | | | | | |
| | material | | | | | | | |
| | Amount | 0.2% | | — | 0.2% | 0.2% | 0.2% | 0.2% |
| | Second | — | | Dye-3 | Dye-3 | Dye-3 | Dye-3 | Dye-3 |
| | coloring | | | | | | | |
| | material | | | | | | | |
| | Amount | — | | 0.8% | 0.5% | 0.4% | 0.5% | 0.5% |
| | Third | — | | — | — | Dye-4 | — | — |
| | coloring | | | | | | | |
| | material | | | | | | | |
| | Amount | — | | — | — | 1.3% | — | — |
| Energy | Type | DCPA | DCPM | DCPA/510H | | | | |
| radiation- | No. of | 2 | 2 | 2/10 | | | | |
| curable | functional | | | | | | | |
| compound | groups | | | | | | | |
| | Amount | 42.7% | | 25.3%/16.8% | 25.3%/16.9% | 24.6%/16.4% | 22.0%/14.7% | 20.2%/13.5% |
| Initiator | Type | Omnirad TPO | | | | | | |
| | Amount | 4.6% | | | | | | |
| Radical | Type | LA-63P | | | | | Resin 1 | |
| scavenger | Amount | 2.5% | | | | | 8.00% | |
| Additive | Type | — | — | — | — | — | — | T1477/D1781 |
| | Amount | — | — | — | — | — | — | 1.5%/1.5% |
| UV | Type | | | | | | | |
| absorber | Amount | | | | | | | |

| | | |
|---|---|---|
| Solvent | Type | MEK/methyl acetate |
| | Amount | 50% |

TABLE 8

| Coating liquid for | | Colored | Colored | Colored | Colored | Colored | Colored | Colored |
|---|---|---|---|---|---|---|---|---|
| colored layer | | layer 2-1 | layer 2-2 | layer 2-3 | layer 2-4 | layer 2-5 | layer 2-6 | layer 2-7 |
| Coloring | First | Dye-1 | | Dye-1 | | Dye-1 | Dye-1 | Dye-1 |
| material | coloring | | | | | | | |
| | material | | | | | | | |
| | Amount | 0.2% | | 0.2% | | 0.2% | 0.2% | 0.2% |
| | Second | — | | — | Dye-3B | Dye-3 | Dye-3 | — |
| | coloring | | | | | | | |
| | material | | | | | | | |
| | Amount | — | | — | 0.8% | 0.5% | 0.5% | — |
| | Third | — | | — | — | — | — | — |
| | coloring | | | | | | | |
| | material | | | | | | | |
| | Amount | — | | — | — | — | — | — |
| Energy | Type | DPHA | PE4A | DCPA | DCPA/510H | | | PMMA |
| radiation- | No. of | 6 | 4 | 2 | 2/10 | | | Polymer |
| curable | functional | | | | | | | |
| compound | groups | | | | | | | |
| | Amount | 42.7% | | | 25.3%/16.8% | 5%/37.2% | 23.4%/15.6% | 14.8% |
| Initiator | Type | Omnirad TPO | | | | | | |
| | Amount | 4.6% | | | | | | |
| Radical | Type | LA-63P | | — | LA-63P | | | |
| scavenger | Amount | 2.5% | | — | 2.5% | | | |
| Additive | Type | — | — | — | — | — | — | |
| | Amount | — | — | — | — | — | — | |
| UV | Type | | | | | | | |
| absorber | Amount | | | | | | | |

| Solvent | Type | MEK/methyl acetate | |
|---|---|---|---|
| | Amount | 50% | 85% |

### (Transparent Substrate)

The following films were used for the transparent substrates.
TAC: A triacetyl cellulose film (TG60UL manufactured by FUJIFILM Corporation, substrate thickness 60 μm, ultraviolet shielding rate 92.9%).
PMMA: A polymethyl methacrylate film (manufactured by Sumitomo Chemical Co., Ltd., W002N80, substrate thickness 80 μm, ultraviolet shielding rate 13.9%)

### (Formation of Colored Layer)

The compositions for forming colored layers shown in Tables 7 and 8 were applied onto the transparent substrates shown in Tables 5 and 6, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan) so that a colored layer having a film thickness of 5.0 μm after curing was formed. Note that the amount added is expressed in mass ratio (mass %). In the tables, “-” signifies that the component is not present.

### [Formation of Functional Layer: Hard Coat Layer]

### (Materials of Composition for Forming Hard Coat Layer)

The following materials were used for the composition for forming the hard coat layer.

### —Active Energy Radiation-Curable Resin

UA-306H: Pentaerythritol triacrylate hexamethylene diisocyanate urethane prepolymer (UA-306H manufactured by Kyoeisha Chemical Co., Ltd.)
DPHA
PE-3A: Pentaerythritol triacrylate (Light Acrylate PE-3A manufactured by Kyoeisha Chemical Co., Ltd.)

### —Photoinitiator

Omnirad TPO: An acyl phosphine oxide photoinitiator (manufactured by IGM Resins B.V.)

### Additive (Ultraviolet (UV) Absorber)

Tinuvin 479: A hydroxyphenyltriazine ultraviolet absorber, Tinuvin (registered trademark) 479 (manufactured by BASF Japan Ltd.).
LA-36: A benzotriazole ultraviolet absorber, ADEKA STAB (registered trademark) LA-36 (manufactured by ADEKA CORPORATION).

### Solvent

MEK: Methyl ethyl ketone
Methyl acetate

Using these, the two kinds of coating liquids for hard coat layers shown in Table 9 were prepared.

TABLE 9

| | | Hard coat layer 1 | Hard coat layer 2 |
|---|---|---|---|
| Active energy | Type | UA-306H/DPHA/PE3A | |
| radiation- | Ratio | 70/20/10 | |
| curable resin | Amount | 45.4% | 42.2% |
| Photoinitiator | Type | Omnirad TPO | |
| | Amount | 4.6% | |
| UV absorber | Type | | Tinuvin 479/LA-36 |
| | Ratio | | 40/60 |
| | Amount | | 3.2% |

| | | |
|---|---|---|
| Solvent | Type | MEK/methyl acetate |
| | Ratio | 50/50 |
| | Amount | 50% |

### (Formation of Hard Coat Layer)

The corresponding coating liquids for hard coat layers were applied onto the transparent substrates or colored layers shown in Tables 5 and 6, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan) so that a hard coat layer having a film thickness of 5.0 m after curing was formed. A hard coat layer 1 does not absorb ultraviolet light, whereas a hard coat layer 2 absorbs ultraviolet light.

### [Formation of Functional Layer: Antiglare Layer B]

### (Composition for Forming Antiglare Layer)

The following materials were used for the composition for forming an antiglare layer B.

### —Active Energy Radiation-Curable Resin

43.7 parts by mass of PE-3A

### —Photoinitiator

4.55 parts by mass of Omnirad TPO (manufactured by IGM Resins B.V.)—Resin particles
0.5 part by mass of styrene-methyl methacrylate copolymer particles (refractive index 1.515, average particle size 2.0 μm)

### —Fine Inorganic Particles

0.25 parts by mass of synthetic smectite
1.0 parts by mass of alumina nanoparticles (average particle size 40 nm)

### —Solvent

15 parts by mass of toluene
35 parts by mass of isopropyl alcohol

### (Formation of Antiglare Layer)

The above composition for forming an antiglare layer was applied onto a transparent substrate shown in Table 5, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan) so that the antiglare layer B having a film thickness of 5.0 μm after curing was formed.

### (Formation of Functional Layer: Low Refractive Index Layer)

### (Composition for Forming the Low Refractive Index Layer)

The following materials were used for the composition for forming the low refractive index layer.

### —Refractive Index Modifier

8.5 parts by mass of a dispersion of fine, porous silica particles (average particle size 75 nm, solid content 20%) in methyl isobutyl ketone

### Antifouling Agent

5.6 parts by mass of Optool (registered trademark) AR-110 (manufactured by Daikin Industries, Ltd., solid content 15%, solvent: methyl isobutyl ketone)

### —Active Energy Radiation-Curable Resin

0.4 parts by mass of PE-3A

### —Photoinitiator

0.07 parts by mass of Omnirad TPO (manufactured by IGM Resins B.V.)

### —Leveling Agent

1.7 parts by mass of RS-77 (manufactured by DIC Corporation)

### —Solvent

83.73 parts by mass of methyl isobutyl ketone

### (Formation of Low Refractive Index Layer)

The above composition for forming the low refractive index layer was applied onto the hard coat layers or the antiglare layers shown in Tables 5 and 6, and dried in an oven at 80° C. for 60 seconds. After that, the coating film was cured by irradiating it with ultraviolet light at an irradiation dose of 200 mJ/cm² using an ultraviolet irradiation device (a light source, H-bulb, manufactured by Fusion UV Systems Japan) so that a low refractive index layer having a film thickness of 100 nm after curing was formed.

The layers of each optical film are laminated in the order shown in Tables 5 and 6. For example, in the optical film 2-1 of Example 2-1, a colored layer 2-1, the substrate (TAC), the hard coat layer 1, and the low refractive index layer are laminated in this order. That is, the transparent substrate is above the colored layer in Example 2-1. In the optical film 2-10 of Example 2-10, the substrate (PMMA), a colored layer 2-7, the hard coat layer 2, and the low refractive index layer are laminated in this order. That is, the colored layer is above the substrate in Example 2-10.

The following evaluations were performed on the optical films according to the Examples.

### [Evaluation of Film Characteristics]

### <Ultraviolet Shielding Rate on Colored Layer>

When the transparent substrate was provided above the colored layer, the transmittance was measured using an automatic spectrophotometer (U-4100 manufactured by Hitachi, Ltd.). When the colored layer was provided above the substrate, the layers above the colored layer were peeled off using a transparent pressure-sensitive adhesive tape that satisfies the JIS-K 5600-5-6:1999 adhesion test. Then, using an adhesive tape as a reference, the transmittance of the layers above the colored layer was measured with an automatic spectrophotometer (U-4100 manufactured by Hitachi, Ltd.). These transmittance values were used to calculate the average transmittance [%] in the ultraviolet region (290 nm to 400 nm), and the ultraviolet shielding rate [%] was obtained by subtracting the average transmittance [%] in the ultraviolet region (290 nm to 400 nm) from 100%.

### <Light Resistance Test>

In the light resistance test of the obtained optical films, the films were tested using a xenon weather meter testing machine (X75 manufactured by Suga Test Instruments Co., Ltd.) for 120 hours with a xenon lamp illuminance of 60 W/m² (300 nm to 400 nm) and at a temperature of 45° C. and humidity (RH) of 50% inside the testing machine. Using an automatic spectrophotometer (U-4100 manufactured by Hitachi, Ltd.), the transmittance was measured before and after the test to calculate a transmittance difference ΔTλ1 before and after the test at a wavelength λ1 at which the minimum transmittance was obtained before the test within the wavelength range of 470 nm to 530 nm, as well as a transmittance difference ΔTλ2 before and after the test at a wavelength λ2 at which the minimum transmittance was obtained before the test within the wavelength range of 560 nm to 620 nm. In other words, the wavelength λ1 is the wavelength at which the minimum transmittance is provided by the first coloring material having a wavelength of maximum absorption in the range of 470 to 530 nm, and the wavelength λ2 is the wavelength at which the minimum transmittance by the second coloring material having a wavelength of maximum absorption in the range of 560 to 620 nm. The closer the transmittance difference is to zero, the better, and preferably |ΔTλN|≤15 (N=1 to 3), more preferably |ΔTλN|≤10(N=1 to 3).

The evaluation was based on the following three levels, and samples that were not rated as “bad” were considered to have passed.
Excellent: |ΔTλN|≤10
Good: 10<|ΔTλN|≤15
Bad: 15<|ΔTλN|

### <Heat Resistance Test>

In the heat resistance test of the obtained optical films, the films were tested for 500 hours at a temperature of 90° C. Using an automatic spectrophotometer (U-4100 manufactured by Hitachi, Ltd.), the transmittance was measured before and after the test to calculate a transmittance difference ΔTλ1 before and after the test at a wavelength λ1 at which the minimum transmittance is obtained before the test within the wavelength range of 470 nm to 530 nm, as well as a transmittance difference ΔTλ2 before and after the test at a wavelength λ2 at which the minimum transmittance is obtained before the test within the wavelength range of 560 nm to 620 nm. The closer the transmittance difference is to zero, the better, and preferably |ΔTλN|≤15 (N=1 to 3), more preferably |ΔTλN|≤10 (N=1 to 3).

The evaluation was based on the following three levels, and samples that were not rated as “bad” were considered to have passed.
Excellent: |ΔTλN|≤10
Good: 10<|ΔTλN|≤15
Bad: 15<|ΔTλN|

### <Infrared Absorption Spectrum>

The infrared absorption spectrum in the range of 4000 cm⁻¹ to 400 cm⁻¹ was measured before and after the light resistance test by the ATR method using FT-IR6300 manufactured by JASCO Corporation. Further, the value of the above formula (1B) was calculated based on the measurement results.

### <Pencil Hardness Test>

For each Example, in accordance with JIS-K 5400-1990, a pencil hardness test was performed on the surface of the colored layer using a Clemens-type scratch hardness tester (HA-301, manufactured by TESTER SANGYO CO., LTD.) and a pencil (UNI, pencil hardness H, manufactured by Mitsubishi Pencil Co., Ltd.) to which a load of 500 g is applied. The change in appearance due to scratches were evaluated visually, and samples were rated as “Pass” when no scratches were observed, and “Fail” when scratches were observed.

### [Evaluation of Display Device Characteristics]

### <White Display Transmission Characteristics>

The transmittance of the obtained optical films was measured with an automatic spectrophotometer (U-4100 manufactured by Hitachi, Ltd.). Using this transmittance, the efficiency of light transmitted through the optical film during white display was calculated and used as an evaluation of the white display transmission characteristics. As a reference, the efficiency of the spectrum during the white display output through a white organic EL light source and a color filter having the spectrum shown in FIG. 7 was set as 100. The closer it is to 100, the higher the white display transmittance and the better the luminance efficiency.

### <Display Device Reflection Characteristic>

The transmittance T(λ) and surface reflectance R2(λ) were measured for each of the obtained optical films using an automatic spectrophotometer (U-4100). To measure the surface reflectance R2(λ), a matte black dye was applied to the surface of the transparent substrate on which the colored layer and functional layer are not formed to prevent reflection, and the spectral reflectance was measured at an incident angle of 5° and used as the surface reflectance R2(λ). Assuming that the electrode reflectance RE(λ) is 100% throughout the wavelength range of 380 nm to 780 nm, without considering any interface reflection or surface reflection at each layer, and setting the reflectance of the display device without the optical film for D65 illuminant (Commission Internationale de l'Eclairage (CIE) standard illuminant D65) as 100, the relative reflection was calculated based on the following formulas (1) to (4). The surface reflectance R(λ) of the outermost layer on the observer's side was used as an evaluation of the display device reflection characteristic. The lower the value of the display device reflection characteristic, the more the reflection of external light can be reduced and the better the reflection characteristic. Note that, in formulas (1) to (4), R1(λ) represents an internal reflection component, Y represents one of the tristimulus values at the white point of the light source D65, PD65(λ) represents the spectrum of D65 illuminant, and overlined y(λ) represents a CIE 1931 color matching function.

$$\begin{matrix}[ Equation 5 ] & \\ R 1 ( λ ) [ \% ] = \frac{( 100 - R 2 ( λ ) )}{100} \times \frac{T ( λ )}{100} \times \frac{T ( λ )}{100} \times {R}_{E} ( λ ) & ( 1 )\end{matrix}$$

$$\begin{matrix}[ Equation 6 ] & \\ R 1 ( λ ) [ \% ] = R 1 ( λ ) + R 2 ( λ ) & ( 2 )\end{matrix}$$

$$\begin{matrix}[ Equation 7 ] & \\ Y = k \times {\int }_{380}^{780} {P}_{D 65} ( λ ) \times R ( λ ) \times \overline{y} ( λ ) d λ & ( 3 )\end{matrix}$$

$$\begin{matrix}[ Equation 8 ] & \\ k = 100 / {\int }_{380}^{780} {P}_{D 65} ( λ ) \times \overline{y} ( λ ) d λ & ( 4 )\end{matrix}$$

### <Color Reproducibility>

The transmittance of the obtained optical films was measured using an automatic spectrophotometer (U-4100), and the red display, green display, and blue display spectra in FIG. 8 output through the white EL light source and color filter having the spectrum shown in FIG. 7 was measured. The vertical axis of the graphs in FIGS. 7 and 8 indicates emission intensity [arbitrary unit (a. u.)]. The National Television Broadcast Standards Committee (NTSC) ratio was calculated from the CIE 1931 chromaticity value calculated using the measured transmittance and the red display, green display, and blue display spectra in FIG. 8. The NTSC ratio was evaluated as a metric of color reproducibility. The higher the NTSC ratio, the better the color reproducibility.

The results are shown in Tables 10 to 12. The evaluation results of the display device characteristics shown in Table 12 were carried out for only some of the examples, and the results for the white display transmission characteristics and display device reflection characteristics also include percentages using the values of Comparative Example 2-8, which does not have a colored layer, as standards (100%).

TABLE 10

| | Ex. 2-1 | Ex. 2-2 | Ex. 2-3 | Ex. 2-4 | Ex. 2-5 |
|---|---|---|---|---|---|
| UV shielding rate on | 92.9% | 92.9% | 92.9% | 92.9% | 92.9% |
| colored layer | | | | | |
| Formula A2 * (B2/C) - D | 0.004 | 0.010 | 0.004 | 0.005 | 0.013 |
| Light resistance | Good | Good | Good | Good | Good |
| Heat resistance | Good | Good | Good | Good | Good |
| Pencil hardness | Pass | Pass | Pass | Pass | Pass |
| | Ex. 2-6 | Ex. 2-7 | Ex. 2-8 | Ex. 2-9 | Ex. 2-10 |
| UV shielding rate on | 92.9% | 92.9% | 92.9% | 92.9% | 90.5% |
| colored layer | | | | | |
| Formula A2 * (B2/C) - D | 0.006 | 0.003 | 0.000 | 0.000 | 0.000 |
| Light resistance | Excellent | Excellent | Excellent | Excellent | Excellent |
| Heat resistance | Good | Excellent | Excellent | Excellent | Excellent |
| Pencil hardness | Pass | Pass | Pass | Pass | Pass |

TABLE 11

| | Comp. | Comp. | Comp. | Comp. | Comp. | Comp. | Comp. | Comp. |
|---|---|---|---|---|---|---|---|---|
| | Ex. 2-1 | Ex. 2-2 | Ex. 2-3 | Ex. 2-4 | Ex. 2-5 | Ex. 2-6 | Ex. 2-7 | Ex. 2-8 |
| UV | 92.9% | 92.9% | 92.9% | 92.9% | 92.9% | 7.2% | 92.9% | 91% |
| shielding | | | | | | | | |
| rate on | | | | | | | | |
| colored | | | | | | | | |
| layer | | | | | | | | |
| A2*(B2/C) − D | 0.020 | 0.037 | 0.043 | 0.004 | 0.037 | 0.045 | 0.000 | — |
| Light | Bad | Bad | Bad | Good | Bad | Bad | Bad | — |
| resistance | | | | | | | | |
| Heat | Bad | Bad | Bad | Good | Bad | Good | Good | — |
| resistance | | | | | | | | |
| Pencil | Pass | Pass | Pass | Pass | Pass | Pass | Fail | — |
| hardness | | | | | | | | |

TABLE 12

| | | Ex. 2-3 | Ex. 2-4 | Ex. 2-5 | Ex. 2-6 | Ex. 2-7 | Ex. 2-8 |
|---|---|---|---|---|---|---|---|
| White display | | 61.0 | 61.4 | 59.1 | 61.4 | 61.4 | 61.4 |
| transmittance | | | | | | | |
| characteristics | | | | | | | |
| | Ratio | 67% | 67% | 65% | 67% | 67% | 67% |
| | to Comp. | | | | | | |
| | Ex. 8 | | | | | | |
| Display device reflectance | | 16.2 | 14.6 | 13.6 | 14.6 | 14.6 | 15.6 |
| characteristics | | | | | | | |
| | Ratio | 48% | 43% | 40% | 43% | 43% | 46% |
| | to Comp. | | | | | | |
| | Ex. 8 | | | | | | |
| Color | NTSC | 100.9% | 98.9% | 97.9% | 98.9% | 98.9% | 98.9% |
| reproducibility | ratio | | | | | | |

| | | | | Comp. | Comp. |
|---|---|---|---|---|---|
| | | Ex. 2-9 | Ex. 2-10 | Ex. 2-4 | Ex. 2-6 |
| White display | | 61.4 | 61.4 | 61.2 | 91.4 |
| transmittance | | | | | |
| characteristics | | | | | |
| | Ratio | 67% | 67% | 67% | 100% |
| | to Comp. | | | | |
| | Ex. 8 | 14.6 | 14.6 | 20.4 | 33.8 |
| Display device reflectance | | 43% | 43% | 60% | 100% |
| characteristics | | | | | |
| | Ratio | | | | |
| | to Comp. | | | | |
| | Ex. 8 | 98.9% | 98.9% | 85.5% | 91.7% |
| Color | NTSC | | | | |
| reproducibility | ratio | | | | |

Among Examples 2-1 to 2-10 and Comparative Examples 2-1 to 2-8, the optical films according to the Examples all satisfied the above formula (1B) and exhibited good light resistance and heat resistance. In addition, they had sufficient hardness because their colored layers contain energy radiation-curable compounds.

The results of Example 2-10 indicate that when the colored layer and the functional layer are provided on the same side of the substrate, and the functional layer formed on the colored layer has sufficient ultraviolet shielding ability, the light resistance and heat resistance of the optical film can be well maintained.

In contrast, the Comparative Examples, which do not satisfy the above formula (1B), did not generally have any problems with hardness, but did not achieve both light resistance and heat resistance.

An embodiment and Examples of the present invention have so far been described in detail. However, the present invention should not be limited to specific embodiments, but should encompass modifications, combinations, or the like of these embodiments, in the range not departing from the spirit of the present invention.

[Reference Signs List]1, 3, 4, 5, 7, 8 . . . Optical film; 10 . . . Colored layer; 20 . . . Transparent substrate; 30 . . . Functional layer; 31 . . . Low refractive index layer; 32 . . . Hard coat layer; 34 . . . Antiglare layer.

What is claimed is:

1. An optical film, comprising:
a sheet-like transparent substrate;
a colored layer formed on a side of a first surface of the transparent substrate; and
a functional layer formed on a second surface of the transparent substrate opposite to the first surface or on the colored layer, wherein
the colored layer is made of a cured product containing a dye (A), an energy radiation-curable compound (B), a photoinitiator (C), and a radical scavenger (D),
the dye (A) contains at least one of a first coloring material, a second coloring material, and a third coloring material,
the first coloring material has a wavelength of maximum absorption within a range of 470 to 530 nm, and a full width at half maximum of an absorption spectrum of 15 to 45 nm,
the second coloring material has a wavelength of maximum absorption within a range of 560 to 620 nm, and a full width at half maximum of an absorption spectrum of 15 to 55 nm,
the third coloring material exhibits, within a wavelength range of 380 to 780 nm, a lowest transmittance in a range of 650 to 780 nm,
at least one of the transparent substrate and the functional layer has an ultraviolet shielding rate of 85% or higher as measured according to JIS L 1925, and
at least one of following item (1) or (2) is satisfied:
(1) when an infrared absorption spectrum peak intensity of the colored layer in a range of 780 to 825 cm⁻¹ is A and an infrared absorption spectrum peak intensity of pentaerythritol tetraacrylate in the range of 780 to 825 cm⁻¹ is B, A/B is 0.01 or more and 0.25 or less, and
(2) in a light resistance test in which a xenon lamp with an illuminance of 60 W/cm² (300 to 400 nm) is used to irradiate the optical film from a side of the colored layer for 120 hours under conditions of a temperature of 45° C. and a humidity (RH) of 50% inside a tester, a following formula 1B is satisfied.
$$A 2 \times ( B 2 / C ) - D \leq 0.018 \qquad ( 1 B )$$
[In the above formula (1B), A2 is an infrared absorption spectrum peak intensity at 3450 cm⁻¹ when a straight line connecting absorbances at 3800 cm⁻¹ and 2400 cm⁻¹ is used as a baseline in an infrared absorption spectrum obtained by spectroscopy of reflected light generated by irradiating a surface of the colored layer with infrared light after the light resistance test. B2 is a maximum absorption peak intensity in an infrared absorption spectrum in a range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light before the light resistance test. C is a maximum absorption peak intensity in an infrared absorption spectrum in the range of 1650 cm⁻¹ to 1815 cm⁻¹ when a straight line connecting absorbances at 1650 cm⁻¹ and 1815 cm⁻¹ is used as a baseline in an infrared absorption spectrum obtained by spectroscopy of reflected light generated by irradiating the surface of the colored layer with infrared light after the light resistance test. D is an infrared absorption spectrum peak intensity at 3450 cm⁻¹ when a straight line connecting absorbances at 3800 cm⁻¹ and 2400 cm⁻¹ is used as a baseline in an infrared absorption spectrum obtained by spectroscopy of reflected light generated by irradiating the surface of the colored layer with infrared light before the light resistance test.]

2. The optical film of claim 1, wherein the energy radiation-curable compound (B) contains 20 wt % or more of a compound having only two (meth)acryloyl groups.

3. The optical film of claim 1, wherein the radical scavenger (D) is a polymer with a structural unit represented by a following formula (i), 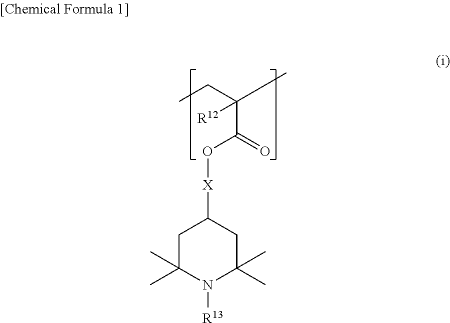
[In the above formula (i), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group; R¹³ represents a hydrogen atom or an alkyl group having 30 or less carbon atoms; and X represents a single bond, an ester group, an aliphatic alkyl chain having 30 or less carbon atoms, an aromatic chain, a polyethylene glycol chain, or a linking group formed by combination thereof, and any of these can contain a spirodioxane ring.]

4. The optical film of claim 1, wherein the functional layer functions as at least one of an antireflection layer and an antiglare layer.

5. The optical film of claim 1, comprising an antistatic layer or an antifouling layer as the functional layer.

6. The optical film of claim 1, wherein the dye (A) contains one or more selected from the group consisting of compounds having a porphyrin structure, merocyanine structure, phthalocyanine structure, azo structure, cyanine structure, squarylium structure, coumarin structure, polyene structure, quinone structure, tetradiporphyrin structure, pyrromethene structure, and indigo structure; and a metal complex thereof.

7. The optical film of claim 1, wherein the optical film satisfies the item (1), and the colored layer has at least one of a singlet oxygen quencher and a peroxide decomposer.

8. The optical film of claim 7, wherein the optical film satisfies the item (1), and the singlet oxygen quencher is any one of dialkyldithiophosphate, dialkyldithiocarbanate, benzenedithiol, and transition metal complexes thereof.

9. The optical film of claim 1, wherein the optical film satisfies the item (2), and
the colored layer contains any one of dialkyldithiophosphate, dialkyldithiocarbanate, benzenedithiol, and transition metal complexes thereof, and a compound represented by a following formula (ii). 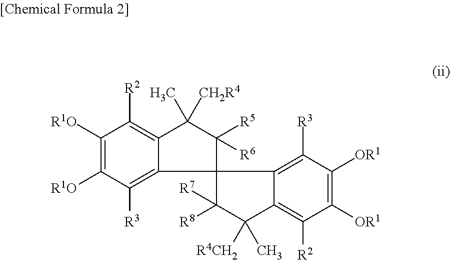
[In the above formula (ii), each R¹ independently represents an alkyl group, an alkenyl group, an aryl group, a heterocyclic group, or R⁹CO—, R¹⁰SO₂—, or R¹¹NHCO—, R⁹, R¹⁰, and R¹¹ are each independently an alkyl group, an alkenyl group, an aryl group, or a heterocyclic group. R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.]

10. The optical film of claim 1, wherein the optical film satisfies the item (2), and a surface of the colored layer has a pencil hardness of H or higher under a load of 500 g.

11. A display device comprising the optical film of claim 1.
